(19) United States
(12) Patent Application Publication
(10) Pub. No.: US 2026/0198203 A1
(43) Pub. Date: Jul. 9, 2026

(54) DISPLAY DEVICE

(71) Applicant: Magnolia White Corporation, Tokyo (JP)

(72) Inventors: Yozo NAKAYASU, Tokyo (JP); Tomokazu ISHIKAWA, Tokyo (JP); Sho YANAGISAWA, Tokyo (JP); Ryota TAKASAKI, Tokyo (JP)

(73) Assignee: Magnolia White Corporation, Tokyo (JP)

(21) Appl. No.: 19/437,368

(22) Filed: Dec. 31, 2025

(30) Foreign Application Priority Data
Jan. 6, 2025 (JP) 2025-001823

(51) Int. Cl. H10K 59/80; H10K 59/12; H10K 59/122

(52) U.S. Cl. CPC H10K 59/871; H10K 59/1201; H10K 59/122

(57) ABSTRACT

According to one embodiment, a display device includes a rib layer including a plurality of pixel apertures respectively located in a first lower electrode and a second lower electrode, a partition surrounding each of the plurality of pixel apertures, a first stacked film provided above the first lower electrode, a second stacked film provided above the second lower electrode, a first sealing layer covering the first stacked film, and provided above the partition, and a second sealing layer covering the second stacked film, and provided above the partition. The first sealing layer and the second sealing layer contact each other above the partition. The first sealing layer includes at least one exposing portion exposing the partition in plan view.

### CROSS-REFERENCE TO RELATED APPLICATIONS

This application is based upon and claims the benefit of priority from Japanese Patent Application No. 2025-001823, filed Jan. 6, 2025, the entire contents of which are incorporated herein by reference.

### FIELD

Embodiments described herein relate generally to a display device.

### BACKGROUND

Recently, display devices with organic light-emitting diodes (OLED) applied thereto as display elements have been put into practical use. This type of display devices demand a technique for improving display quality.

### BRIEF DESCRIPTION OF THE DRAWINGS

FIG. 1 is a view showing a configuration example of a display device according to the first embodiment.

FIG. 2 is a schematic plan view showing an example of the layout of subpixels constituting one pixel.

FIG. 3 is a schematic cross-sectional view of the display device along the III-III line of FIG. 2.

FIG. 4 is a schematic cross-sectional view of another example of the display device along the III-III line of FIG. 2.

FIG. 5 is a schematic plan view showing some elements of the display device.

FIG. 6 is a schematic plan view showing configuration examples applicable to a partition and a sealing layer according to the first embodiment.

FIG. 7 is a schematic cross-sectional view of the display device DSP along the VII-VII line of FIG. 6.

FIG. 8 is a schematic cross-sectional view of the display device DSP along the VIII-VIII line of FIG. 6.

FIG. 9 is a flowchart showing an example of a manufacturing method of the display device.

FIG. 10A is a schematic cross-sectional view showing a manufacturing process of the display device.

FIG. 10B is a schematic cross-sectional view showing a process following the one shown in FIG. 10A.

FIG. 10C is a schematic cross-sectional view showing a process following the one shown in FIG. 10B.

FIG. 10D is a schematic cross-sectional view showing a process following the one shown in FIG. 10C.

FIG. 10E is a schematic cross-sectional view showing a process following the one shown in FIG. 10D.

FIG. 10F is a schematic cross-sectional view showing a process following the one shown in FIG. 10E.

FIG. 10G is a schematic cross-sectional view showing a process following the one shown in FIG. 10F.

FIG. 10H is a schematic cross-sectional view showing a process following the one shown in FIG. 10G.

FIG. 10I is a schematic cross-sectional view showing a process following the one shown in FIG. 10H.

FIG. 10J is a schematic cross-sectional view showing a process following the one shown in FIG. 10I.

FIG. 11A is a schematic plan view showing another configuration example applicable to the sealing layer according to the first embodiment.

FIG. 11B is a schematic plan view showing another configuration example applicable to the sealing layer according to the first embodiment.

FIG. 11C is a schematic plan view showing another configuration example applicable to the sealing layer according to the first embodiment.

FIG. 12 is a schematic plan view showing configuration examples applicable to a partition and a sealing layer according to the second embodiment.

FIG. 13 is a schematic cross-sectional view of the display device along the XIII-XIII line of FIG. 12.

FIG. 14 is a schematic plan view showing another configuration example applicable to the sealing layer according to the second embodiment.

FIG. 15 is a schematic plan view showing configuration examples applicable to a partition and a sealing layer according to the third embodiment.

FIG. 16A is a schematic plan view showing another configuration example applicable to the sealing layer according to the third embodiment.

FIG. 16B is a schematic plan view showing another configuration example applicable to the sealing layer according to the third embodiment.

FIG. 17 is a schematic plan view showing configuration examples applicable to a partition and a sealing layer according to the fourth embodiment.

FIG. 18 is a schematic plan view showing configuration examples applicable to a partition and a sealing layer according to the fifth embodiment.

FIG. 19 is a schematic cross-sectional view of the display device along the XIX-XIX line of FIG. 18.

FIG. 20 is a schematic cross-sectional view of the display device along the XX-XX line of FIG. 18.

### DETAILED DESCRIPTION

In general, according to one embodiment, a display device includes a display area in which a plurality of pixels each including a first lower electrode and a second lower electrode are provided, a rib layer including a plurality of pixel apertures respectively located in the first lower electrode and the second lower electrode, a partition surrounding each of the plurality of pixel apertures and including a conductive lower portion provided above the rib layer and an upper portion having an end portion protruding relative to a side surface of the lower portion, a first stacked film provided above the first lower electrode and including a first organic layer, a second stacked film provided above the second lower electrode and including a second organic layer different from the first organic layer, a first sealing layer formed of an inorganic insulating material, covering the first stacked film, and provided above the partition, and a second sealing layer formed of an inorganic insulating material, covering the second stacked film, and provided above the partition. The first sealing layer and the second sealing layer contact each other above the partition. The first sealing layer includes at least one exposing portion recessed toward the pixel aperture and exposing the partition in plan view.

According to another embodiment, a display device includes a display area in which a plurality of pixels each including a first lower electrode, a second lower electrode, and a third lower electrode are provided, a rib layer including a plurality of pixel apertures respectively located in the first lower electrode, the second lower electrode, and the third lower electrode, a partition surrounding each of the plurality of pixel apertures and including a conductive lower portion provided above the rib layer and an upper portion having an end portion protruding relative to a side surface of the lower portion, a first stacked film provided above the first lower electrode and including a first organic layer, a second stacked film provided above the second lower electrode and including a second organic layer different from the first organic layer, a third stacked film provided above the third lower electrode and including a third organic layer different from the first organic layer and the second organic layer, a first sealing layer formed of an inorganic insulating material, covering the first stacked film, and provided above the partition, a second sealing layer formed of an inorganic insulating material, covering the second stacked film, and provided above the partition, and a third sealing layer formed of an inorganic insulating material, covering the third stacked film, and provided above the partition. The plurality of pixels include a first pixel and a second pixel arranged in a first direction. The first sealing layer and the second sealing layer are arranged with the third sealing layer in the first direction. The first sealing layer and the second sealing layer are arranged in a second direction orthogonal to the first direction. The partition includes a first slit extending in the second direction between the first pixel and the second pixel. The first sealing layer, the second sealing layer, and the third sealing layer contact each other above the partition. The first sealing layer includes a first protrusion portion located higher than the second sealing layer and the third sealing layer above the partition. The first sealing layer covers an end portion of the upper portion located on a side of the first slit. The first stacked film is located between the partition and the first sealing layer.

This configuration can provide a display device capable of improving display quality.

Embodiments will be described hereinafter with reference to the accompanying drawings. The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes and the like, of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis, and a Z-axis orthogonal to each other are described to facilitate understanding as needed. A direction parallel to the X-axis is referred to as a first direction X. A direction parallel to the Y-axis is referred to as a second direction Y. A direction parallel to the Z-axis is referred to as a third direction Z. A plan view is defined as appearance when various types of elements are viewed parallel to the third direction Z.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone, and a wearable terminal.

### First Embodiment

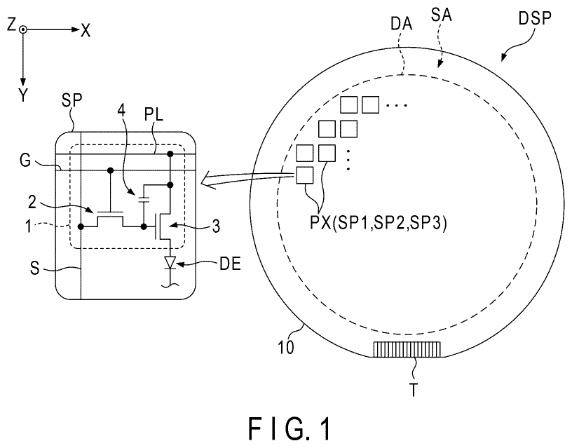

FIG. 1 is a view showing a configuration example of a display device DSP according to the present embodiment. The display device DSP comprises an insulating substrate 10. The substrate 10 has a display area DA for displaying images and a surrounding area SA around the display area DA. The substrate 10 may be glass or a resinous film having flexibility.

In the present embodiment, the substrate 10 and the display area DA have a circular shape in plan view. The shape of each of the substrate 10 and the display area DA in plan view is not limited to a circular shape and may be another shape such as a rectangular shape, a square shape, or an elliptic shape.

The display area DA comprises a plurality of pixels PX arranged in a matrix in the first direction X and the second direction Y. Each pixel PX includes a plurality of subpixels SP that display different colors. The present embodiment assumes a case where each pixel PX includes a blue subpixel SP1, a green subpixel SP2, and a red subpixel SP3. Each pixel PX may include a subpixel SP that exhibits another color such as white in addition to the subpixels SP1, SP2, and SP3 or instead of one of the subpixels SP1, SP2, and SP3.

The display device DSP further comprises a terminal portion T provided in the surrounding area SA. For example, a flexible printed circuit board, which applies voltage and signals for driving the display device DSP is connected to the terminal portion T.

The subpixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements constituted by thin-film transistors.

The display area DA has a plurality of scanning lines G supplying the pixel circuit 1 of each subpixel SP with scanning signals, a plurality of signal lines S supplying the pixel circuit 1 of each subpixel SP with video signals, and a plurality of power lines PL. In the example of FIG. 1, the scanning lines G and the power lines PL extend in the first direction X, and the signal lines S extend in the second direction Y.

The gate electrode of the pixel switch 2 is connected to the scanning line G. One of a source electrode and a drain electrode of the pixel switch 2 is connected to the signal line S. The other is connected to a gate electrode of the drive transistor 3 and the capacitor 4. In the drive transistor 3, one of a source electrode and a drain electrode is connected to the power line PL and the capacitor 4. The other is connected to the display element DE.

The configuration of the pixel circuit 1 is not limited to the example of the figure. For example, the pixel circuit 1 may comprise more thin-film transistors and more capacitors.

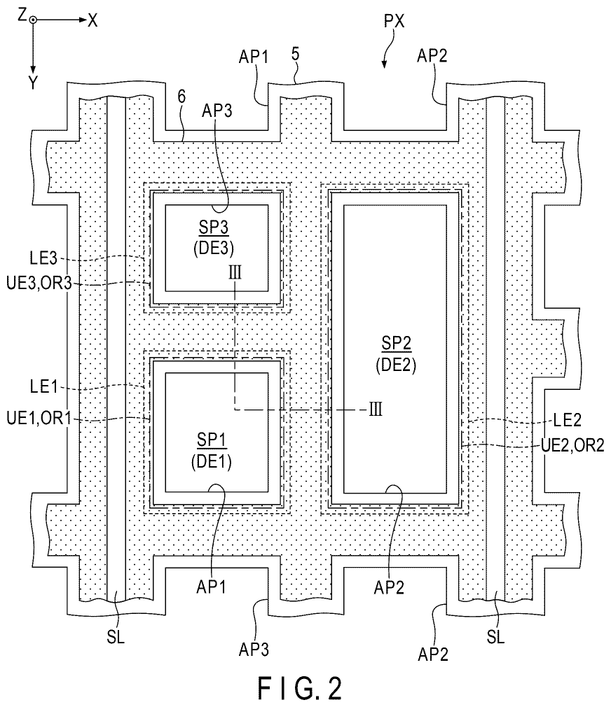

FIG. 2 is a schematic plan view showing an example of the layout of the subpixels SP1, SP2, and SP3 constituting one pixel PX. In the example of FIG. 2, the subpixels SP1 and SP3 are arranged in the second direction Y. Each of the subpixels SP1 and SP3 is arranged with the subpixel SP2 in the first direction X.

When the subpixels SP1, SP2, and SP3 are arranged in this layout, in the display area DA, a column in which the subpixels SP1 and SP3 are alternately arranged in the second direction Y and a column in which the plurality of subpixels SP2 are arranged in the second direction Y are formed. These columns are alternately arranged in the first direction X. The layout of the subpixels SP1, SP2, and SP3 is not limited to the example of FIG. 2.

A rib layer 5 (an inorganic insulating layer) is provided in the display area DA. The rib layer 5 has pixel apertures AP1, AP2, and AP3 in the respective subpixels SP1, SP2, and SP3. In the example of FIG. 2, each of the pixel apertures AP1, AP2, and AP3 has a rectangular shape. The planar size of the pixel aperture AP1 is greater than that of the pixel aperture AP3. The planar size of the pixel aperture AP2 is greater than that of the pixel aperture AP1. The pixel aperture AP2 is a rectangle extending longer in the second direction Y more than the pixel apertures AP1 and AP3. The shapes of the pixel aperture AP1, AP2, and AP3 are not limited to this example.

The subpixel SP1 comprises a lower electrode LE1, an upper electrode UE1, and an organic layer OR1, which overlap the pixel aperture AP1. The subpixel SP2 comprises a lower electrode LE2, an upper electrode UE2, and an organic layer OR2, which overlap the pixel aperture AP2. The subpixel SP3 comprises a lower electrode LE3, an upper electrode UE3, and an organic layer OR3, which overlap the pixel aperture AP3.

Parts overlapping the pixel aperture AP1 of the lower electrode LE1, the upper electrode UE1, and the organic layer OR1 constitute a display element DE1 of the subpixel SP1. Parts overlapping the pixel aperture AP2 of the lower electrode LE2, the upper electrode UE2, and the organic layer OR2 constitute a display element DE2 of the subpixel SP2. Parts overlapping the pixel aperture AP3 of the lower electrode LE3, the upper electrode UE3, and the organic layer OR3 constitute a display element DE3 of the subpixel SP3. Each of the display elements DE1, DE2, and DE3 may further include a cap layer to be described later. The rib layer 5 surrounds each of the display elements DE1, DE2, and DE3.

A conductive partition 6 is provided above the rib layer 5. The partition 6 functions as lines which apply common voltage to the upper electrodes UE1, UE2, and UE3. The partition 6 entirely overlaps the rib layer 5 and has the same planar shape as that of the rib layer 5. The partition 6 is formed to surround the lower electrodes LE1, LE2, and LE3 and the pixel apertures AP1, AP2, and AP3.

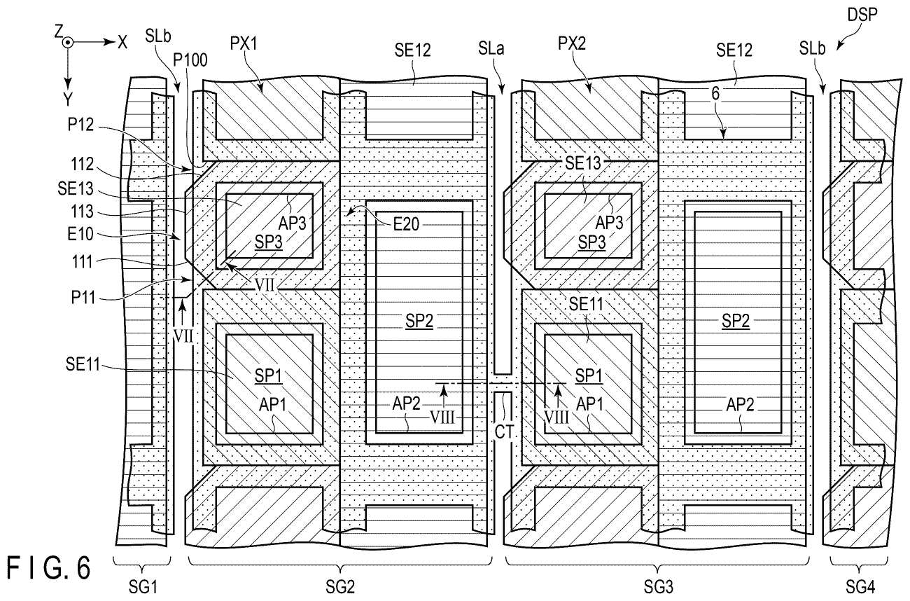

The partition 6 has a plurality of slits SL. In the example of FIG. 2, each of the slits SL extends in the second direction Y. For example, the subpixels SP1, SP2, and SP3 constituting one pixel PX are provided between two slits SL adjacent to each other in the first direction X. Further, the partition 6 may have a connecting portion (shown in FIG. 6), which connects portions divided by the slit SL (segments to be described later) to each other.

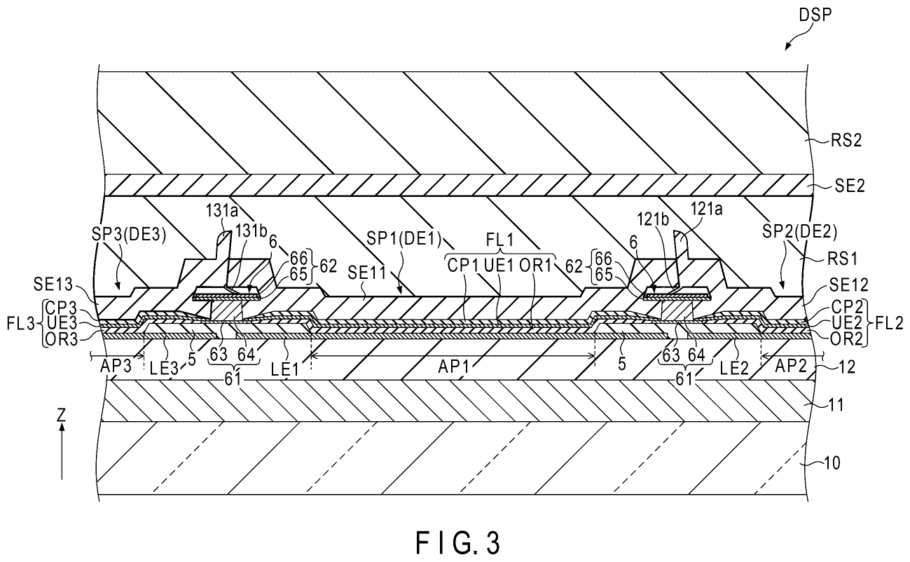

FIG. 3 is a schematic cross-sectional view of the display device DSP along the III-III line of FIG. 2. A circuit layer 11 is provided on the substrate 10 described above. The circuit layer 11 includes various circuits and lines such as the pixel circuit 1, the scanning line G, the signal line S, and the power line PL shown in FIG. 1. The circuit layer 11 is covered with an organic insulating layer 12. The organic insulating layer 12 functions as a planarization film which planarizes irregularities formed by the circuit layer 11.

The lower electrodes LE1, LE2, and LE3 are provided on the organic insulating layer 12. The rib layer 5 is provided on the organic insulating layer 12 and the lower electrodes LE1, LE2, and LE3. End portions of the lower electrodes LE1, LE2, and LE3 are covered with the rib layer 5. Although not shown in the section of FIG. 3, the lower electrodes LE1, LE2 and LE3 are connected to the respective pixel circuits 1 of the circuit layer 11 through respective contact holes provided in the organic insulating layer 12.

The partition 6 includes a conductive lower portion 61 provided on the rib layer 5 and an upper portion 62 provided on the lower portion 61. The upper portion 62 has a width greater than that of the lower portion 61. This configuration allows both end portions of the upper portion 62 to protrude relative to the side surfaces of the lower portion 61. This shape of the partition 6 is called an overhang shape.

In the example of FIG. 3, the lower portion 61 has a bottom layer 63 provided on the rib layer 5, and a stem layer 64 provided on the bottom layer 63. For example, the bottom layer 63 is formed to be thinner than the stem layer 64. In the example of FIG. 3, both end portions of the bottom layer 63 protrude relative to the side surfaces of the stem layer 64.

In the example of FIG. 3, the upper portion 62 includes a first top layer 65 and a second top layer 66 provided on the first top layer 65. For example, the width of the second top layer 66 is slightly less than that of the first top layer 65. The configuration is not limited to this example. The first top layer 65 and the second top layer 66 may have the same width.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2, and UE3 contact the lower portion 61 of the partition 6.

The display element DE1 includes a cap layer CP1 covering the upper electrode UE1. The display element DE2 includes a cap layer CP2 covering the upper electrode UE2. The display element DE3 includes a cap layer CP3 covering the upper electrode UE3. The cap layers CP1, CP2, and CP3 function as optical adjustment layers which improve the extraction efficiency of the light emitted from the respective organic layers OR1, OR2, and OR3.

In the following explanation, a multilayer body including the organic layer OR1, the upper electrode UE1, and the cap layer CP1 is called a stacked film FL1. A multilayer body including the organic layer OR2, the upper electrode UE2, and the cap layer CP2 is called a stacked film FL2. A multilayer body including the organic layer OR3, the upper electrode UE3, and the cap layer CP3 is called a stacked film FL3.

The stacked films FL1, FL2, and FL3 are provided above the lower electrodes LE1, LE2, and LE3. Further, the rib layer 5 is provided below the partition 6 and the stacked films FL1, FL2, and FL3. Sealing layers SE11, SE12, and SE13 are provided in the respective subpixels SP1, SP2, and SP3.

The sealing layer SE11 continuously covers the display element DE1 including the stacked film FL1 and the partition 6 around the display element DE1. The sealing layer SE12 continuously covers the display element DE2 including the stacked film FL2 and the partition 6 around the display element DE2. The sealing layer SE13 continuously covers the display element DE3 including the stacked film FL3 and the partition 6 around the display element DE3.

The sealing layers SE11, SE12, and SE13 are covered with a resin layer RS1. The resin layer RS1 is covered with the sealing layer SE2. The sealing layer SE2 is covered with a resin layer RS2. The resin layers RS1 and RS2 and the sealing layer SE2 are continuously provided in at least the entire display area DA and partly extend in the surrounding area SA as well.

A cover member such as a polarizer, a touch panel, a protective film, and a cover glass may be further provided above the resin layer RS2. This cover member may be attached to the resin layer RS2 via, for example, an adhesive layer such as an optical clear adhesive (OCA). Electrodes constituting the touch panel may be provided on the sealing layer SE2.

In the example of FIG. 3, the end portions of the sealing layers SE11 and SE12 contact each other (closely contact each other) above the partition 6 between the subpixels SP1 and SP2. Further, the end portions of the sealing layers SE11 and SE13 contact each other (closely contact each other) above the partition 6 between the subpixels SP1 and SP3. Further, though not illustrated, the end portions of the sealing layers SE12 and SE13 contact each other (closely contact each other) above the partition 6 between the subpixels SP2 and SP3. Here, the end portion signifies an end and an area near the end.

With respect to the sealing layer SE12, the end portion of the sealing layer SE12 is located above the partition 6. The end portion of the sealing layer SE12 contacts the end portion of the sealing layer SE11. The end portion of the sealing layer SE12 may include a protrusion portion 121a protruding upward. Further, the protrusion portion 121a is located higher than the sealing layer SE11 above the partition 6 between the subpixels SP1 and SP2.

The end portion of the sealing layer SE12 may further include an extending portion 121b extending toward a gap formed between the sealing layer SE11 and the upper portion 62 of the partition 6. The gap is formed by removing the stacked film FL1 during the manufacturing process. A gap is also formed between the sealing layer SE12 and the upper portion 62 of the partition 6 by removing the stacked film FL2 during the manufacturing process.

With respect to the sealing layer SE13, the end portion of the sealing layer SE13 is located above the partition 6. The end portion of the sealing layer SE13 contacts the end portion of the sealing layer SE11. The end portion of the sealing layer SE13 may include a protrusion portion 131a protruding upward. Further, the protrusion portion 131a is located higher than the sealing layer SE11 above the partition 6 between the subpixels SP1 and SP3.

The end portion of the sealing layer SE13 may further include an extending portion 131b extending toward a gap formed between the sealing layer SE11 and the upper portion 62 of the partition 6. In the present embodiment, a gap is also formed between the partition 6 and the sealing layer SE13 by removing the stacked film FL3 during the manufacturing process.

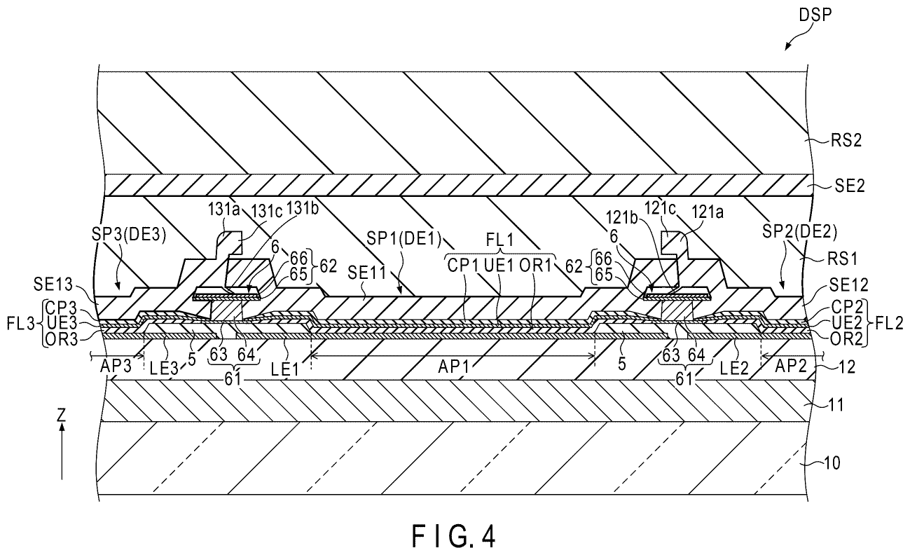

FIG. 4 is a schematic cross-sectional view of the display device DSP along the III-III line of FIG. 2. The example of FIG. 4 differs from the example of FIG. 3 in the shape of the end portions of the sealing layers SE12 and SE13.

With respect to the sealing layer SE12, the protrusion portion 121a of the sealing layer SE12 may overlap the sealing layer SE11. In the example of FIG. 4, the protrusion portion 121a includes a part 121c overlapping the sealing layer SE11. In the third direction Z, the partition 6, the sealing layer SE11, and the protrusion portion 121a of the sealing layer SE12 are arranged in this order. The part 121c may or may not contact the sealing layer SE11.

Similarly, with respect to the sealing layer SE13, the protrusion portion 131a of the sealing layer SE13 overlaps the sealing layer SE11. In the example of FIG. 4, the protrusion portion 131a includes a part 131c overlapping the sealing layer SE11. In the third direction Z, the partition 6, the sealing layer SE11, and the protrusion portion 131a of the sealing layer SE13 are arranged in this order. The portion 131c may or may not contact the sealing layer SE11.

Above the partition 6 between the subpixels SP2 and SP3, the end portion of the sealing layer SE13 may include the protrusion portion 131a protruding upward. This configuration is not shown in FIG. 3 and FIG. 4. The protrusion portion 131a is located higher than the sealing layer SE12. In the example of FIG. 4, the protrusion portion 131a includes the part 131c overlapping the sealing layer SE12. Above the partition 6 between the subpixels SP2 and SP3, the partition 6, the sealing layer SE12, and the protrusion portion 131a of the sealing layer SE13 are arranged in this order in the third direction Z.

The organic insulating layer 12 is formed of an organic insulating material such as a polyimide. Each of the rib layer 5 and the sealing layers SE11, SE12, SE13, and SE2 is formed of an inorganic insulating material such as a silicon nitride (SiNx), a silicon oxide (SiOx), or a silicon oxynitride (SiON). In one example, the rib layer 5 is formed of a silicon oxynitride, and each of the sealing layers SE11, SE12, SE13, and SE2 is formed of a silicon nitride. Each of the resin layers RS1 and RS2 is formed of, for example, resinous materials (organic insulating materials) such as an epoxy resin or an acrylic resin.

Each of the lower electrodes LE1, LE2, and LE3 has a reflective layer formed of, for example, silver, and a pair of conductive oxide layers covering the upper and lower surfaces of the reflective layer. Each of the conductive oxide layers can be formed of, for example, a transparent conductive oxide such as an indium tin oxide (ITO), an indium zinc oxide (IZO), or an indium gallium zinc oxide (IGZO).

The upper electrodes UE1, UE2, and UE3 are formed of, for example, a metal material such as an alloy of magnesium and silver (MgAg). For example, the lower electrodes LE1, LE2, and LE3 correspond to anodes, and the upper electrodes UE1, UE2, and UE3 correspond to cathodes.

Each of the organic layers OR1, OR2, and OR3 is formed of a plurality of thin films including a light emitting layer. The light emitting layers included in the organic layers OR1, OR2, and OR3 differ from each other. As an example, each of the organic layers OR1, OR2, and OR3 has a structure in which a hole-injection layer, a hole-transport layer, an electron blocking layer, a light emitting layer, a hole blocking layer, an electron-transport layer, and an electron-injection layer are stacked in this order in the third direction Z. The organic layers OR1, OR2, and OR3 each may comprise other structures such as a tandem structure including a plurality of light emitting layers.

Each of the cap layers CP1, CP2, and CP3 comprises, for example, a multilayer structure in which a plurality of transparent layers are stacked. These transparent layers may include a layer formed of an inorganic material and a layer formed of an organic material. The transparent layers have refractive indices different from each other. For example, the refractive indices of these transparent layers are different from the refractive indices of the upper electrodes UE1, UE2, and UE3 and the refractive indices of the sealing layers SE11, SE12, and SE13. At least one of the cap layers CP1, CP2, and CP3 may be omitted.

For example, each of the bottom layer 63 and the stem layer 64 of the partition 6 is formed of a metal material. For the metal material of the bottom layer 63, for example, molybdenum, titanium, titanium nitride (TiN), a molybdenum-tungsten alloy (MoW), or a molybdenum-niobium alloy (MoNb) can be used. For the metal material of the stem layer 64, for example, aluminum, an aluminum-neodymium alloy (AlNd), an aluminum-yttrium alloy (AlY), or an aluminum-silicon alloy (AlSi) can be used. The stem layer 64 may be formed of an insulating material.

The first top layer 65 of the partition 6 is formed of, for example, a metal material. The second top layer 66 of the partition 6 is formed of, for example, a conductive oxide. For the metal material forming the first top layer 65, for example, titanium, a titanium nitride, molybdenum, tungsten, a molybdenum-tungsten alloy, or a molybdenum-niobium alloy can be used. For the conductive oxide forming the second top layer 66, for example, an ITO or an IZO can be used. The upper portion 62 may comprise three or more layers or may consist of a single layer. The upper portion 62 may further include a layer formed of an insulating material.

The partition 6 is supplied with common voltage. This common voltage is applied to each of the upper electrodes UE1, UE2, and UE3 contacting the lower portions 61. The lower electrodes LE1, LE2, and LE3 are supplied with pixel voltages according to the video signals of the signal lines S through the respective pixel circuits 1 provided in the subpixels SP1, SP2, and SP3.

The organic layers OR1, OR2, and OR3 emit light in response to the application of a voltage. Specifically, when a potential difference is formed between the lower electrode LE1 and the upper electrode UE1, the light emitting layer of the organic layer OR1 emits light in the blue wavelength range. When a potential difference is formed between the lower electrode LE2 and the upper electrode UE2, the light emitting layer of the organic layer OR2 emits light in the green wavelength range. When a potential difference is formed between the lower electrode LE3 and the upper electrode UE3, the light emitting layer of the organic layer OR3 emits light in the red wavelength range.

As another example, the light emitting layers of the organic layers OR1, OR2, and OR3 may emit light of the same color (for example, white). In this case, the display device DSP may comprise a color filter that converts the light emitted from the light emitting layers into light of the colors corresponding to those of the subpixels SP1, SP2, and SP3. Further, the display device DSP may comprise a layer including quantum dots that are excited by the light emitted from the light emitting layers to generate the light of the colors corresponding to those of the subpixels SP1, SP2, and SP3.

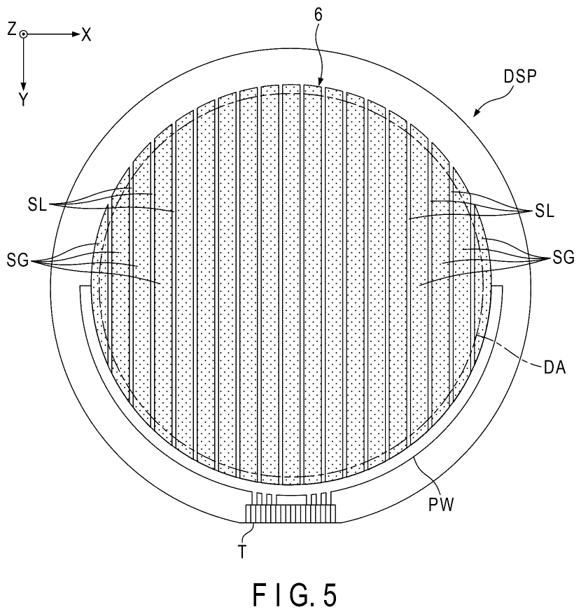

FIG. 5 is a schematic plan view showing some elements of the display device DSP. The partition 6 is divided into a plurality of segments SG by a plurality of slits SL shown in FIG. 2 as well. FIG. 5 schematically shows the slits SL and the segments SG. For example, when the slits SL are located on respective sides of the pixel PX in the first direction X as shown in FIG. 2, more slits SL are formed in the display area DA.

Each of the segments SG is connected to a power supply line PW provided in the surrounding area SA. The power supply line PW is connected to the terminal portion T. Common voltage is applied from the terminal portion T to each of the segments SG via the power supply line PW.

FIG. 6 is a schematic plan view showing configuration examples applicable to the partition 6 and the sealing layers SE11, SE12, and SE13 according to the present embodiment. This figures shows the partition 6 is illustrated with a dotted pattern, the sealing layer SE11 with right-downward slant lines, the sealing layer SE12 with horizontal lines, and the sealing layer SE13 with right-upward slant lines.

FIG. 6 shows four segments SG1, SG2, SG3, and SG4 arranged in the first direction X of the partition 6. These segments SG1, SG2, SG3, and SG4 are divided by three slits SL.

The partition 6 further includes a plurality of connecting portions CT. The segments SG2 and SG3 are connected by the plurality of connecting portions CT (only one of them is shown in FIG. 6). In contrast, the segments SG1 and SG2 are not connected to each other by the connecting portion CT. The segments SG3 and SG4 are not connected to each other by the connecting portion CT, either.

Each slit SL contributes to improving the transmittance of the display device DSP. Thus, for example, when an optical sensor is provided on the back side of the display device DSP, the detection capability of the sensor can be enhanced.

Further, as a specific aspect of the display device DSP, a configuration in which antennas are arranged on the rear surface and the short-range wireless communication is achieved through these antennas is assumed. In this form of use, the magnetic field during the communication may generate an eddy current in the partition 6, decreasing the signal strength. In this case, a slit SL having no connection portion CT can suppress the generation of an eddy current having the size great enough to spread in the entire display area DA. As a result, this slit SL can suppress decreases in the signal strength.

In the following description, a slit SL including the connecting portion CT, such as the one between the segments SG2 and SG3, is referred to as a slit SLa, and a slit SL without any connecting portion CT, such as those between the segments SG1 and SG2 or between the segments SG3 and SG4, is referred to as a slit SLb. The connecting portion CT extends across the slit SLa.

In the example of FIG. 6, the connecting portion CT is provided at the position aligned with the subpixel SP1 in the first direction X. The connecting portion CT may be provided on the side of each of the subpixels SP1 of the segments SG3. Alternatively, the connecting portion CT may be provided on the side of only some of the subpixels SP1.

Here, the pixel shown in FIG. 6 including the sealing layers SE11, SE12, and SE13 of the segment SG2 is shown as a pixel PX1. Similarly, the pixel shown in FIG. 6 including the sealing layers SE11, SE12, and SE13 of the segments SG3 is shown as a pixel PX2. The pixels PX1 and PX2 are arranged in the first direction X. The slit SLa extends in the second direction Y between the pixels PX1 and PX2.

Next, the following will describe the sealing layer provided for each pixel PX.

The sealing layers SE11, SE12, and SE13 are provided in the respective subpixels SP1, SP2, and SP3. The sealing layers SE11 and SE13 are arranged in the second direction Y. The sealing layer SE12 is formed continuously across the plurality of subpixels SP2 arranged in the second direction Y. Each of the sealing layers SE11 and SE13 is aligned with the sealing layer SE12 in the first direction X.

With respect to one pixel PX, the end portions of the sealing layers SE11, SE12, and SE13 contact each other (closely contact) above the partition 6, as described with reference to FIG. 3 and FIG. 4. The sealing layers SE11 and SE13 contact the sealing layer SE12 in the first direction X. The sealing layer SE11 contacts the sealing layer SE13 in the second direction Y.

With respect to the plurality of pixels PX arranged in the second direction Y, the sealing layers SE11 and SE13 are alternately arranged in the second direction Y, and their end portions contact each other. The cross-sectional shape of the end portions of the sealing layers SE11, SE12, and SE13 are the same as the shape described, for example, with reference to FIG. 3 and FIG. 4.

The end portions of the sealing layers SE11 and SE12 entirely overlap the partition 6 in plan view. In contrast, part of the end portion of the sealing layer SE13 overlaps the slits SL (the slits SLa and SLb). Part of the end portions of the sealing layers SE11 and SE12 may overlap the slit SL, or the end portions of the sealing layers SE11 and SE12 may be aligned with the end of the partition 6.

The following will describe the sealing layer SE13, specifically on its shape.

The sealing layer SE13 includes end portions E10 and E20. The end portion E10 is located on the slit SL side, and the end portion E20 is located on the side opposite to the end portion E10 in the first direction X. The end of the end portion E20 contacts the sealing layer SE12. Each of the end portions of the sealing layer SE13 in the second direction Y contacts the sealing layer SE11.

The sealing layer SE13 includes at least one exposing portion. That is, part of the sealing layer SE13 is cut out. In the example shown in FIG. 6, the end portion E10 includes exposing portions P11 and P12. That is, the sealing layer SE13 includes a plurality of exposing portions, for example, two exposing portions.

The exposing portions P11 and P12 are provided on respective sides in the second direction Y of the end portion E10 of the sealing layer SE13. The exposing portions P11 and P12 are formed to be recessed toward the pixel aperture AP3.

With respect to the relationship between these portions and the partition 6, the exposing portions P11 and P12 overlap the partition 6. The exposing portions P11 and P12 expose the upper portion 62 of the partition 6 (shown in FIG. 3 and FIG. 4) in plan view. The exposed parts are covered with the resin layer RS1 (shown in FIG. 3 and FIG. 4).

The end portion E10 includes ends 111 and 112 located above the partition 6. In plan view, for example, the end 111 extends in a direction forming an acute angle clockwise with respect to the first direction X, and, for example, the end 112 extends in a direction forming an acute angle counterclockwise with respect to the first direction X. The inclination angles of the ends 111 and 112 can be modified as appropriate. The ends 111 and 112 do not overlap the pixel aperture AP3.

The end portion E10 further includes an end 113 connecting the ends 111 and 112 to each other. The end 113 extends in the second direction Y. The end 113 overlaps the slit SL. Part of the ends 111 and 112 overlap the slit SL. At the end portion of the sealing layer SE11 in the second direction Y, a part P100 is formed above the upper portion of the partition 6. The part P100 faces the ends 111 and 112 and does not contact the sealing layer SE13.

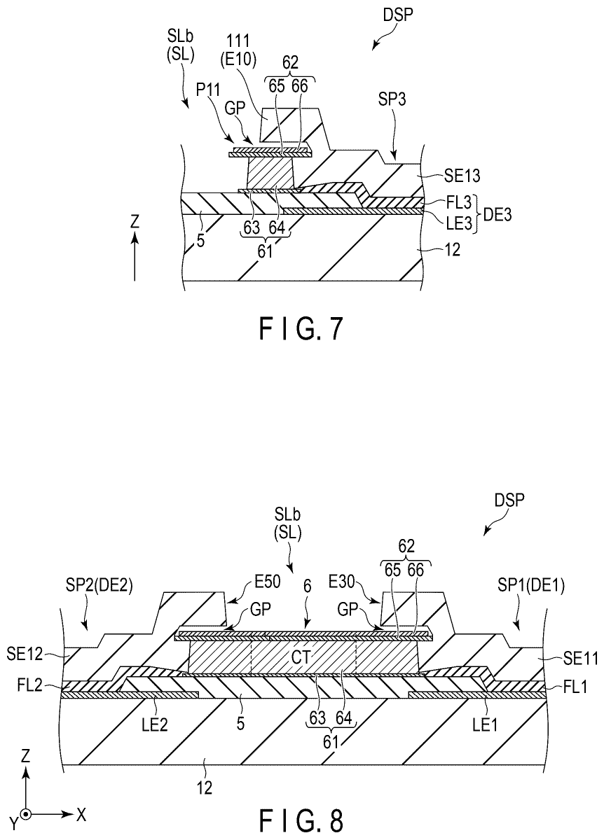

FIG. 7 is a schematic cross-sectional view of the display device DSP along the VII-VII line of FIG. 6. FIG. 8 is a schematic cross-sectional view of the display device DSP along the VIII-VIII line of FIG. 6. These figures omit the illustration of elements under the organic insulating layer 12 and the elements above the sealing layers SE11, SE12, and SE13.

As shown in FIG. 7, the side portion along the slit SLb of the partition 6 has an overhang shape in which the upper portion 62 protrudes relative to the side surface of the stem layer 64. For example, the rib layer 5 is not open in the slit SLb. Similarly, the side portion along the slit SLa of the partition 6 has an overhang shape in which the upper portion 62 protrudes relative to the side surface of the stem layer 64. For example, the rib layer 5 is not open in the slit SLa.

As shown in FIG. 8, the connecting portion CT has the lower portion 61 (the bottom layer 63 and the stem layer 64) and the upper portion 62 (the first top layer 65 and the second top layer 66) in the same manner as the other parts of the partition 6. An end portion E30 of the sealing layer SE11 and an end portion E50 of the sealing layer SE12 are located above the partition 6. The end portion E30 of the sealing layer SE11 is spaced apart from the end portion E50 of the sealing layer SE12. That is, the sealing layers SE11, SE12, and SE13 do not overlap the connecting portion CT.

In each of FIG. 7 and FIG. 8, gaps GP are formed under the end portions E10, E30, and E50. These gaps GP are open toward the slits SL (the slits SLa and SLb). That is, these gaps GP are not blocked. At least part of the gap GP is filled with the resin layer RS1.

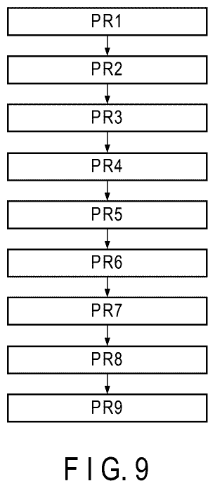

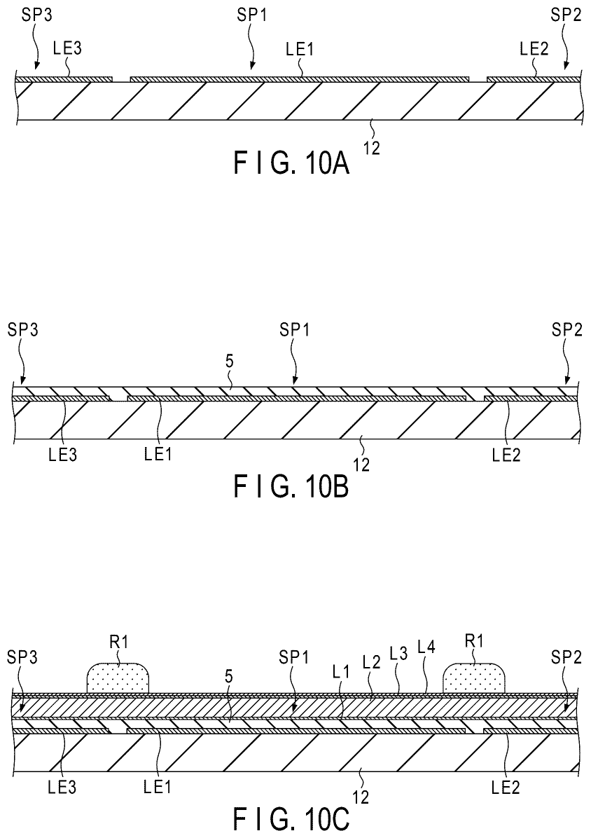

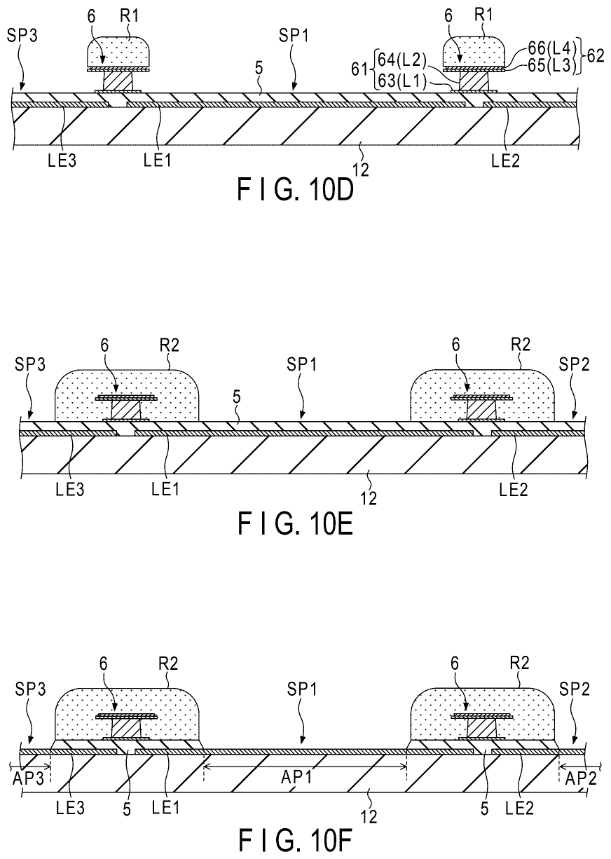

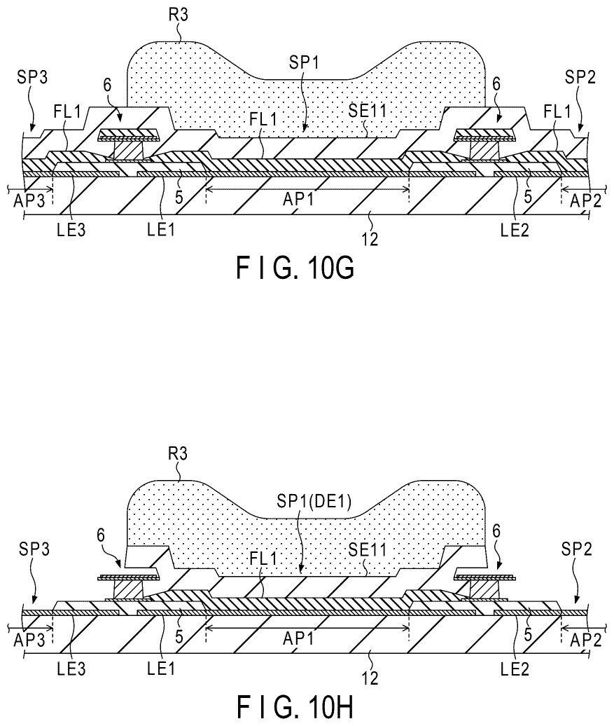

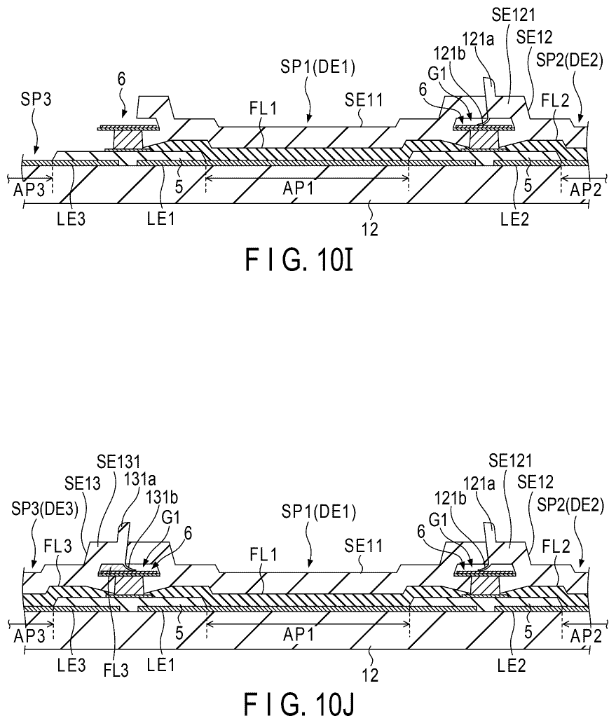

The following will describe an example of the manufacturing method of the display device DSP. FIG. 9 is a flowchart showing an example of the manufacturing method of the display device DSP. FIG. 10A to FIG. 10J are schematic cross-sectional views showing the manufacturing process of the display device DSP. FIG. 10A to FIG. 10J mainly focus on the display area DA and omit the illustration of elements under the organic insulating layer 12.

In the formation of the display device DSP, first, the circuit layer 11 and the organic insulating layer 12 are formed on the substrate 10 (the process PR1 in FIG. 9). Next, as shown in FIG. 10A, the lower electrodes LE1, LE2, and LE3 are formed on the organic insulating layer 12 (the process PR2 in FIG. 9).

Subsequently, as shown in FIG. 10B, the rib layer 5 covering the lower electrodes LE1, LE2, and LE3 is formed (the process PR3 in FIG. 9). At this time, the pixel apertures AP1, AP2, and AP3 are not provided in the rib layer 5. The rib layer 5 can be formed by chemical vapor deposition (CVD).

After the formation of the rib layer 5, a process for forming the partition 6 is performed (the process PR4 in FIG. 9). In the process PR4, as shown in FIG. 10C, a first layer L1 to be processed into the bottom layer 63, a second layer L2 to be processed into the stem layer 64, a third layer L3 to be processed into the first top layer 65, and a fourth layer L4 to be processed into the second top layer 66 are formed sequentially. Further, the resist R1 is provided on the fourth layer L4. The resist R1 is patterned into the shape of the partition 6. The first layer L1, the second layer L2, the third layer L3, and the fourth layer L4 can be formed by sputtering.

Then, the first layer L1, the second layer L2, the third layer L3, and the fourth layer L4 are patterned using the resist R1 as a mask. In one example, the first layer L1 is formed of a titanium nitride, the second layer L2 is formed of aluminum, the third layer L3 is formed of titanium, and the fourth layer L4 is formed of an ITO. In this case, the patterning may include wet etching to remove parts exposed from the resist R1 of the fourth layer L4, dry etching to remove parts exposed from the resist R1 of the first layer L1, the second layer L2, and the third layer L3, and wet etching to reduce the width of the second layer L2.

After the process PR4, as shown in FIG. 10D, the partition 6 is formed in the display region DA. The formed partition 6 includes the slits SL (the slits SLa and SLb) and the connecting portion CT. After the formation of the partition 6, the resist R1 is removed (stripped). In the above-described wet etching to reduce the width of the second layer L2, the second top layer 66 (the fourth layer L4) may also be slightly etched. When such etching occurs, the width of the second top layer 66 becomes smaller than that of the first top layer 65.

Next, a process for forming the pixel apertures AP1, AP2, and AP3 is performed (the process PR5 in FIG. 9). In the process PR5, as shown in FIG. 10E, a resist R2 is formed to cover the partition 6. Further, dry etching is performed on the rib layer 5 using the resist R2 as a mask. Thus, as shown in FIG. 10F, the pixel apertures AP1, AP2, and AP3 are formed in the rib layer 5. The respective lower electrodes LE1, LE2, and LE3 are exposed from the pixel apertures AP1, AP2, and AP3. After the dry etching, the resist R2 is removed (stripped).

After the process PR5, the process for forming the display element DE1 is performed (the process PR6 in FIG. 9). As shown in FIG. 10G, in the formation of the display element DE1, the stacked film FL1 and the sealing layer SE11 are formed first. As shown in FIG. 3, the stacked film FL1 includes the organic layer OR1 contacting the lower electrode LE1 through the pixel aperture AP1, the upper electrode UE1 covering the organic layer OR1, and the cap layer CP1 covering the upper electrode UE1. For example, the organic layer OR1, the upper electrode UE1, and the cap layer CP1 may be formed by vapor deposition. For example, the sealing layer SE11 may be formed by CVD.

The stacked film FL1 and the sealing layer SE11 are formed not only in the display area DA but also in the surrounding area SA. The partition 6 having an overhang shape divides the stacked film FL1 into a plurality of parts. The sealing layer SE11 continuously covers these parts, into which the stacked film FL1 has been divided, and the partition 6.

Subsequently, the stacked film FL1 and the sealing layer SE11 are patterned. As shown in FIG. 10G, a resist R3 is provided on the sealing layer SE11 in this patterning. The resist R3 covers the subpixel SP1 and part of the partition 6 around the subpixel SP1.

Thereafter, the etching process using the resist R3 as a mask is performed. As shown in FIG. 10H, parts exposed from the resist R3 of the stacked film FL1 and the sealing layer SE11 are removed.

That is, parts overlapping the lower electrode LE1 of the stacked film FL1 and the sealing layer SE11 remain. The other parts are removed. Thus, the display element DE1 is formed in the subpixel SP1.

This etching process includes wet etching and dry etching performed in order for the sealing layer SE11, the cap layer CP1, the upper electrode UE1, and the organic layer OR1. After these etching processes, the resist R3 is removed (stripped).

The stacked film FL1 located under the sealing layer SE11 on the partition 6 is also removed in wet etching for the stacked film FL1. This process forms a gap between the sealing layer SE11 located above the partition 6 and the partition 6. The stacked film FL1 constituting the display element DE1 is completely surrounded by the sealing layer SE11 and the partition 6. Thus, this stacked film FL1 is not corroded by the wet etching.

Before the wet etching, the stacked film FL1 is formed in the gap between the partition 6 and the sealing layer SE11 as well. The stacked film FL1 in the gap is removed by penetration of the etching liquid beneath the sealing layer SE11 from the vicinity of its end portion.

After the process PR6, the process for forming the display element DE2 is performed (the process PR7 in FIG. 9). The display element DE2 can be formed by the same procedure as that of the display element DE1. That is, in the formation of the display element DE2, the stacked film FL2 and the sealing layer SE12 are formed in the entire display area DA and in the entire surrounding area SA. As shown in FIG. 3, the stacked film FL2 includes the organic layer OR2 contacting the lower electrode LE2 through the pixel aperture AP2, the upper electrode UE2 covering the organic layer OR2, and the cap layer CP2 covering the upper electrode UE2.

The organic layer OR2, the upper electrode UE2, and the cap layer CP2 may be formed by, for example, vapor deposition. The sealing layer SE12 may be formed by, for example, CVD. The partition 6 having an overhang shape divides the stacked film FL2 into a plurality of parts. The sealing layer SE12 continuously covers these parts, into which the stacked film FL2 has been divided, and the partition 6. Patterning these stacked film FL2 and sealing layer SE12 forms the display element DE2 in the subpixel SP2 as shown in FIG. 10I.

Further, the end portions of the sealing layers SE11 and SE12 contact each other above the partition 6 between the subpixels SP1 and SP2. When the sealing layer SE12 is formed to contact the sealing layer SE11, the protrusion portion 121a may be formed in the sealing layer SE12, which is formed after the formation of the sealing layer SE11. Furthermore, the extending portion 121b extending toward a gap formed between the sealing layer SE11 and the upper portion 62 of the partition 6 may be formed on the sealing layer SE12.

The stacked film FL2 may be formed in the gap between the partition 6 and the sealing layer SE12 as well. The stacked film FL2 in the gap is removed by penetration of the etching liquid beneath the sealing layer SE12 from the vicinity of its end portion.

After the process PR7, the process for forming the display element DE3 is performed (the process PR8 in FIG. 9). The display element DE3 can be formed by the same procedures as those of the display elements DE1 and DE2.

That is, in the formation of the display element DE3, the stacked film FL3 and the sealing layer SE13 are formed in the entire display area DA and in the entire surrounding area SA. As shown in FIG. 3, the stacked film FL3 includes the organic layer OR3 contacting the lower electrode LE3 through the pixel aperture AP3, the upper electrode UE3 covering the organic layer OR3, and the cap layer CP3 covering the upper electrode UE3.

The organic layer OR3, the upper electrode UE3, and the cap layer CP3 may be formed by, for example, vapor deposition. The sealing layer SE13 may be formed by, for example, CVD. The partition 6 having an overhang shape divides the stacked film FL3 into a plurality of parts. The sealing layer SE13 continuously covers these parts, into which the stacked film FL3 has been divided, and the partition 6. As shown in FIG. 10J, patterning these stacked film FL3 and sealing layer SE13 forms the display element DE3 in the subpixel SP3. In this process, patterning is performed such that the sealing layer SE13 has the exposing portions P11 and P12. After the process PR8 shown in FIG. 9, part of the sealing layer SE13 overlaps the slit SL.

Further, the end portions of the sealing layers SE11 and SE13 contact each other above the partition 6 between the subpixels SP1 and SP3. When the sealing layer SE13 is formed to contact the sealing layer SE11, the protrusion portion 131a may be formed in the sealing layer SE13, which is formed after the formation of the sealing layer SE11. Furthermore, the extending portion 131b extending toward a gap formed between the sealing layer SE11 and the upper portion 62 of the partition 6 may be formed on the sealing layer SE13.

Above the partition 6 between the subpixels SP2 and SP3 as well, when the sealing layer SE13 is formed to contact the sealing layer SE12, the protrusion portion 131a and the extending portion 131b extending toward a gap formed between the sealing layer SE12 and the upper portion 62 of the partition 6 may be formed in the sealing layer SE13 formed after the formation of the sealing layer SE12.

The stacked film FL3 may be formed in the gap between the partition 6 and the sealing layer SE13 as well. The stacked film FL3 in the gap is removed by penetration of the etching liquid beneath the sealing layer SE13 from the vicinity of its end portion.

In the examples shown in FIG. 10I and FIG. 10J, the area from a part 121c overlapping the sealing layer SE11 of the sealing layer SE12 to a part 131c overlapping the sealing layer SE11 of the sealing layer SE13 shown in FIG. 4. Patterning may be formed such that the parts 121c and 131c remain.

After the process PR8, the resin layer RS1, the sealing layer SE2, and the resin layer RS2 are sequentially formed (the process PR9 in FIG. 9). The resin layers RS1 and RS2 may be formed by, for example, the ink-jet method. The sealing layer SE2 may be formed by, for example, CVD.

The present embodiment assumes that the display elements DE1, DE2, and DE3 are formed in this order. In this case, the display element DE1 corresponds to the first color display element, the display element DE2 corresponds to the second color display element, and the third display element DE3 corresponds to the third color display element. The display elements DE1, DE2, and DE3 may also be formed in a different order.

As described with reference to FIG. 9 and FIG. 10A to FIG. 10J, during the manufacturing process of the display device DSP, the stacked films FL1, FL2, and FL3 originally formed on the partition 6 are removed to form the gaps GP (shown in FIG. 7 and FIG. 8). That is, the respective stacked films FL1, FL2, and FL3 under the end portions E10, E30, and E50 of the sealing layers SE11, SE12, and SE13 are eroded by various etching solutions to be void.

In one example, the stacked film FL1 and the sealing layer SE11 are formed first, the stacked film FL2 and the sealing layer SE12 are formed second, and the stacked film FL3 and the sealing layer SE13 are formed last.

In this case, among the stacked films FL1, FL2, and FL3, the stacked film FL1 formed first is most prone to removal, while the stacked film FL3 formed last is least prone to removal. Thus, at the positions shown as the gaps GP, the stacked films FL1 and FL2 may potentially be removed but the stacked film FL3 may potentially remain in some cases.

Differences in the degree of removal of the stacked film FL3 above the partition 6 can affect the visual appearance of the display region DA. For example, when external light enters the display area DA with all pixels PX not illuminated, reflection occurs at the remaining parts of the stacked film FL3 but not at the removed parts of the stacked film FL3. Thus, a streak may potentially be visually recognized by a user.

In the present embodiment, the sealing layer SE13, which is formed third, has the exposing portions P11 and P12. The exposing portions P11 and P12 are formed to be recessed toward the pixel opening AP3. Thus, the ends 111 and 112 of the end portion E10 of the sealing layer SE13 are positioned above the partition 6.

In this case, as described with reference to FIG. 7, the gap GP open toward the slit SL is formed. The stacked film FL3 provided in this gap GP is not covered with the sealing layer SE13 and is partially exposed.

Thus, in the process PR8 shown in FIG. 9, the etching liquid readily intrudes between the partition 6 and the end portion E10 of the sealing layer SE13. Further, the stacked film FL3 around the subpixel SP3 also is readily intruded by etching solution and the like via the stacked film FL3 on the partition 6. Thus, the stacked film FL3 hardly remains on the partition 6. Thus, differences in the degree of removal of the stacked film FL3 in the display area DA are minimized.

Consequently, non-uniform reflection caused by differences in the degree of removal of the stacked film FL3 above the partition 6 is suppressed. Thus, the display quality of the display device DSP is improved. The present embodiment can achieve various suitable effects in addition to the above effects.

The following will describe other configuration examples in the present embodiment.

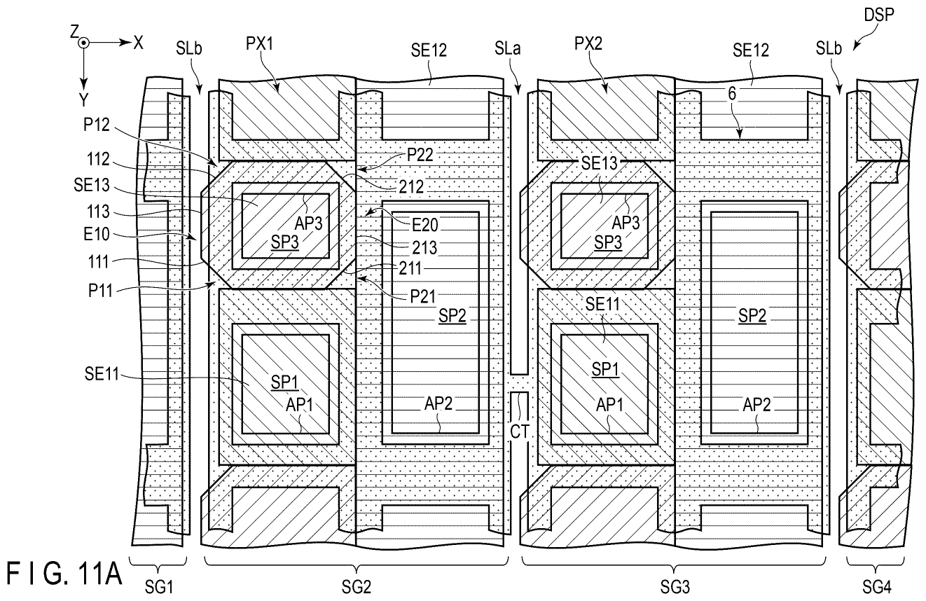

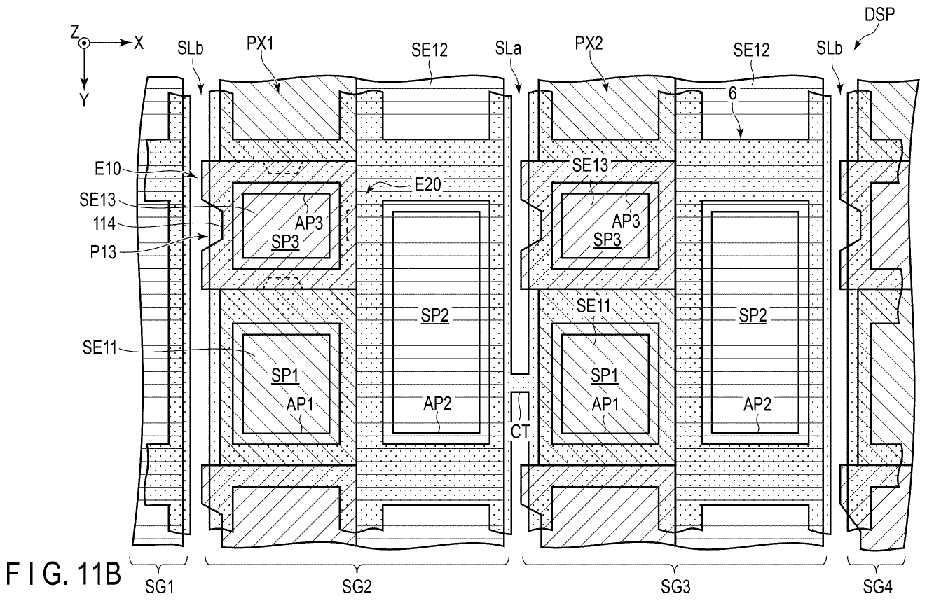

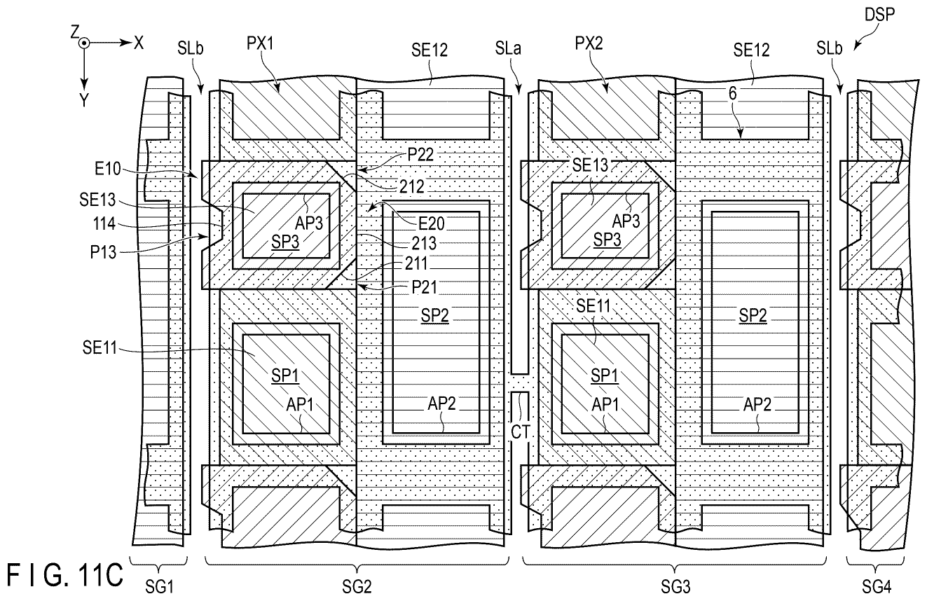

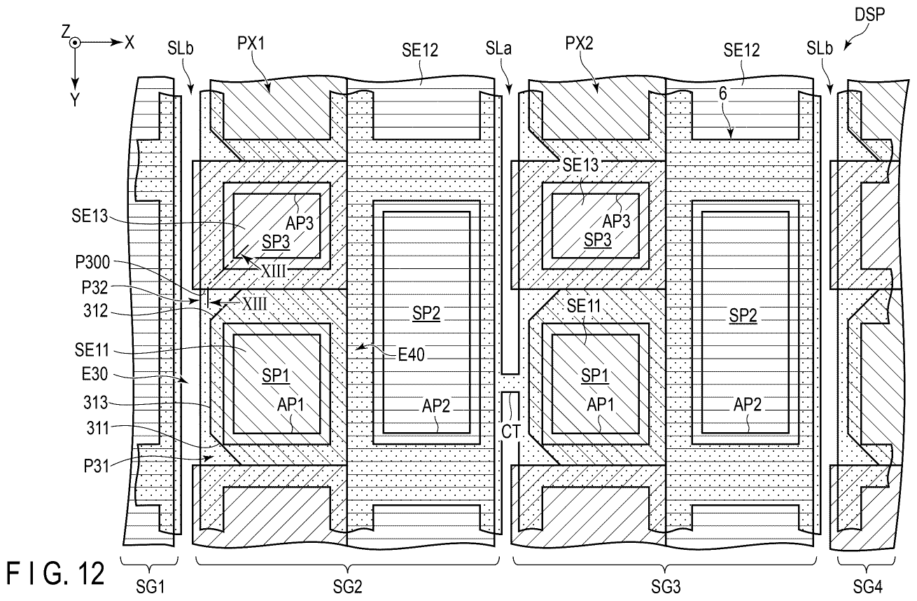

FIG. 11A to FIG. 11C are schematic plan views showing other configuration examples applicable to the sealing layer SE13 according to the present embodiment.

In the example shown in FIG. 11A, each of the end portions E10 and E20 includes at least one exposing portion. More specifically, the end portion E20 further includes exposing portions P21 and P22. That is, the sealing layer SE13 includes four exposing portions P11, P12, P21, and P22.

The exposing portions P21 and P22 are provided on respective sides in the second direction Y of the end portion E20 of the sealing layer SE13. The exposing portions P21 and P22 are formed to be recessed toward the pixel aperture AP3.

With respect to the relationship between these portions and the partition 6, the exposing portions P21 and P22 overlap the partition 6. In plan view, the exposing portions P21 and P22 expose the upper portion 62 of the partition 6 (shown in FIG. 3 and FIG. 4).

The end portion E20 includes ends 211 and 212 located above the partition 6. In plan view, for example, the end 211 extends in a direction forming an acute angle counterclockwise with respect to the first direction X, and, for example, the end 212 extends in a direction forming an acute angle clockwise with respect to the first direction X. The inclination angles of the ends 211 and 212 can be modified as appropriate. The ends 211 and 212 do not overlap the pixel aperture AP3.

The end portion E20 further includes an end 213 connecting the ends 211 and 212 to each other. The end 213 extends in the second direction Y. The end 213 contacts the sealing layer SE12. The ends 211 and 212 entirely overlap the partition 6. In the example shown in FIG. 11A, the exposing portions P21 and P22 further may potentially be an intrusion path of etching liquid and the like that remove the stacked film FL3.

In the example shown in FIG. 11B, the end portion E10 further includes an exposing portion P13 located in the center of the second direction Y. The exposing portion P13 is formed to be recessed toward the pixel aperture AP3. For example, the exposing portion P13 has a trapezoidal shape in plan view.

With respect to the relationship between this portion and the partition 6, the exposing portion P13 overlaps the partition 6. In plan view, the exposing portion P13 exposes the upper portion 62 of the partition 6 (shown in FIG. 3 and FIG. 4). The end portion E10 includes an end 114 located above the partition 6 and extending in the second direction Y. In the example shown in FIG. 11B, the exposing portion P13 may potentially be an intrusion path of etching liquid and the like that remove the stacked film FL3.

In the example of FIG. 11B, the exposing portion P13 is located in the center of the second direction Y of the end portion E10. The configuration is not limited to this example. Further, as indicated by the broken lines in FIG. 11B, the exposing portion P13 may be formed at the end portion E20. Alternatively, the exposing portion P13 may be formed at an end portion of the sealing layer SE13 in the second direction Y. Further, the exposing portion P13 may be formed at a position other than the center of each end portion.

In the example shown in FIG. 11C, the end portion E10 includes one exposing portion P13 located in the center of the second direction Y, and the end portion E20 includes the exposing portions P21 and P22. In this manner, at least one of the end portions E10 and E20 includes at least one exposing portion. The exposing portion need to be formed at either end E10 or end E20. The display device DSP of the examples shown in FIG. 11A to FIG. 11C can achieve the same effects as those described above.

In the present embodiment, the lower electrode LE3 corresponds to the first lower electrode, the lower electrode LE1 corresponds to the second lower electrode, the stacked film FL3 corresponds to the first stacked film, the stacked film FL1 corresponds to the second stacked film, the organic layer OR3 corresponds to the first organic layer, the organic layer OR1 corresponds to the second organic layer, the sealing layer SE13 corresponds to the first sealing layer, the sealing layer SE11 corresponds to the second sealing layer, the pixel PX1 corresponds to the first pixel, the pixel PX2 corresponds to the second pixel, the end portion E10 corresponds to the first end portion, the end portion E20 corresponds to the second end portion, the protrusion portion 131a corresponds to the first protrusion portion, the part 131c corresponds to the part overlapping the second sealing layer, and the extending portion 131b corresponds to the first extending portion.

The following will describe other embodiments. In other embodiments described below, the same constituent elements as those in the first embodiment are denoted by the same reference numerals used in the first embodiment. Explanations of these overlapping constituent elements are omitted or simplified in some cases.

### Second Embodiment

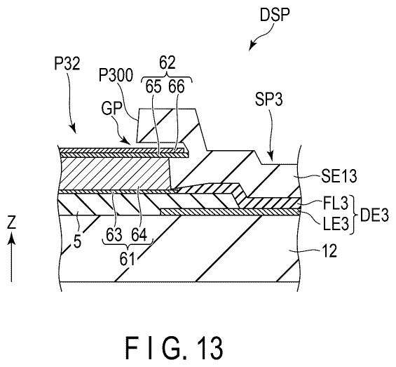

FIG. 12 is a schematic plan view showing configuration examples applicable to the partition 6 and the sealing layers SE11, SE12, and SE13 according to the present embodiment. FIG. 13 is a schematic cross-sectional view of the display device DSP along the XIII-XIII line of FIG. 12. The present embodiment differs from the first embodiment in that the sealing layer SE11 includes an exposing portion.

As shown in FIG. 12, the sealing layer SE11 includes end portions E30 and E40. The end portion E30 is located on the slit SL side, and the end portion E40 is located on the side opposite to the end portion E30 in the first direction X. The end of the end portion E40 contacts the sealing layer SE12.

The sealing layer SE11 includes at least one exposing portion. For example, at least one of the end portions E30 and E40 includes at least one exposing portion. In the example shown in FIG. 12, the end portion E30 includes exposing portions P31 and P32. That is, the sealing layer SE11 includes a plurality of exposing portions, for example, two exposing portions.

The exposing portions P31 and P32 are provided on respective sides in the second direction Y of the end portion E30 of the sealing layer SE11. The exposing portions P31 and P32 are formed to be recessed toward the pixel aperture AP1.

With respect to the relationship between these portions and the partition 6, the exposing portions P31 and P32 overlap the partition 6. In plan view, the exposing portions P31 and P32 expose the upper portion 62 of the partition 6 (shown in FIG. 3 and FIG. 4).

The end portion E30 includes ends 311 and 312 located above the partition 6. In plan view, for example, the end 311 extends in a direction forming an acute angle clockwise with respect to the first direction X, and, for example, the end 312 extends in a direction forming an acute angle counterclockwise with respect to the first direction X. The ends 311 and 312 do not overlap the pixel aperture AP1.

The end portion E30 further includes an end 313 connecting the ends 311 and 312 to each other. The end 313 extends in the second direction Y. The ends 311, 312, and 313 do not overlap the slit SL.

The present embodiment can achieve the same effects as those of the first embodiment. In the present embodiment, the sealing layer SE11, which is formed first, includes the exposing portions P31 and P32. In this case, at the end portion of the sealing layer SE13 in the second direction Y, a part P300 is formed above the upper portion of the partition 6. The part P300 faces the ends 311 and 312 and does not contact the sealing layer SE11.

As shown in FIG. 13, the gap GP between the partition 6 and the sealing layer SE13 is open toward the exposing portion P32 on the part P300. Thus, in the present embodiment as well, the etching liquid readily intrudes between the partition 6 and the sealing layer SE13 in the process PR8 shown in FIG. 9. Thus, the stacked film FL3 hardly remains on the partition 6. Thus, differences in the degree of removal of the stacked film FL3 in the display area DA are minimized.

The following will describe other configuration examples in the present embodiment.

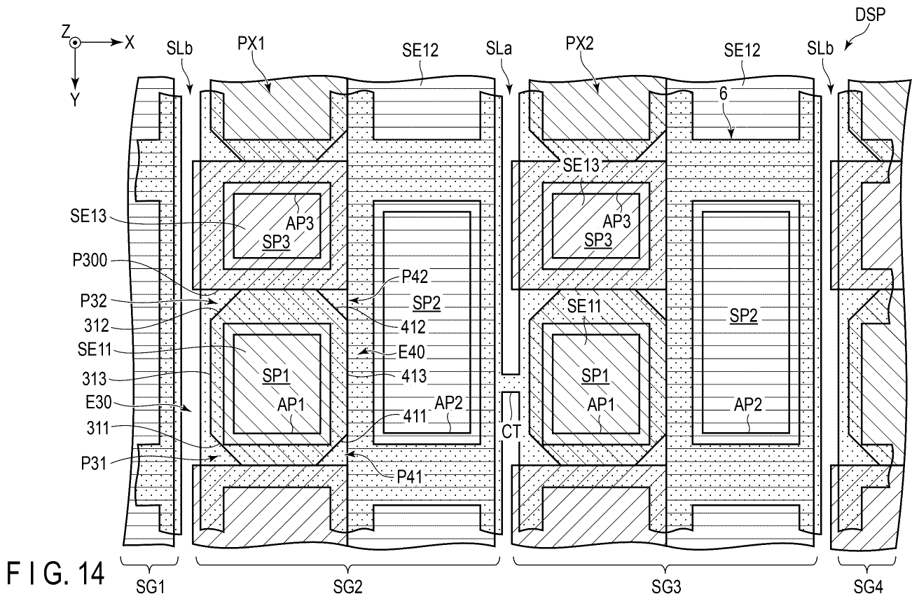

FIG. 14 is a schematic plan view showing another configuration example applicable to the sealing layer SE11 according to the present embodiment.

In the example shown in FIG. 14, each of the end portions E30 and E40 includes at least one exposing portion. More specifically, the end portion E40 further includes exposing portions P41 and P42. That is, the sealing layer SE11 includes four exposing portions P31, P32, P41, and P42.

The exposing portions P41 and P42 are provided on respective sides in the second direction Y of the end portion E40 of the sealing layer SE11. The exposing portions P41 and P42 are formed to be recessed toward the pixel aperture AP1.

With respect to the relationship between these portions and the partition 6, the exposing portions P41 and P42 overlap the partition 6. In plan view, the exposing portions P41 and P42 expose the upper portion 62 of the partition 6 (shown in FIG. 3 and FIG. 4).

The end portion E40 includes ends 411 and 412 located above the partition 6. In plan view, for example, the end 411 extends in a direction forming an acute angle counterclockwise with respect to the first direction X, and, for example, the end 412 extends in a direction forming an acute angle clockwise with respect to the first direction X. The ends 411 and 412 do not overlap the pixel aperture AP1. The end portion E40 further includes an end 413 connecting the ends 411 and 412 to each other. The end 413 extends in the second direction Y. The end 413 contacts the sealing layer SE12. In the example shown in FIG. 14, the exposing portions P41 and P42 further may potentially be an intrusion path of etching liquid and the like that remove the stacked film FL3.

The display device DSP of the example shown in FIG. 14 can achieve the same effects as those described above. The descriptions on the examples of FIG. 12 and FIG. 14 disclose the configuration in which a plurality of exposing portions are formed. Alternatively, only one exposing portion may be formed in the configurations. The descriptions on the examples of FIG. 12 and FIG. 14 disclose the configuration in which the exposing portion is formed at the corner of the sealing layer SE11. The exposing portion may be formed at other locations. For example, the sealing layer SE11 may include an exposing portion located at the center in the second direction Y of the ends E30 and E40.

In the present embodiment, the lower electrode LE1 corresponds to the first lower electrode, the lower electrode LE3 corresponds to the second lower electrode, the stacked film FL1 corresponds to the first stacked film, the stacked film FL3 corresponds to the second stacked film, the organic layer OR1 corresponds to the first organic layer, the organic layer OR3 corresponds to the second organic layer, the sealing layer SE11 corresponds to the first sealing layer, the sealing layer SE13 corresponds to the second sealing layer, the end portion E30 corresponds to the first end portion, and the end portion E40 corresponds to the second end portion.

### Third Embodiment

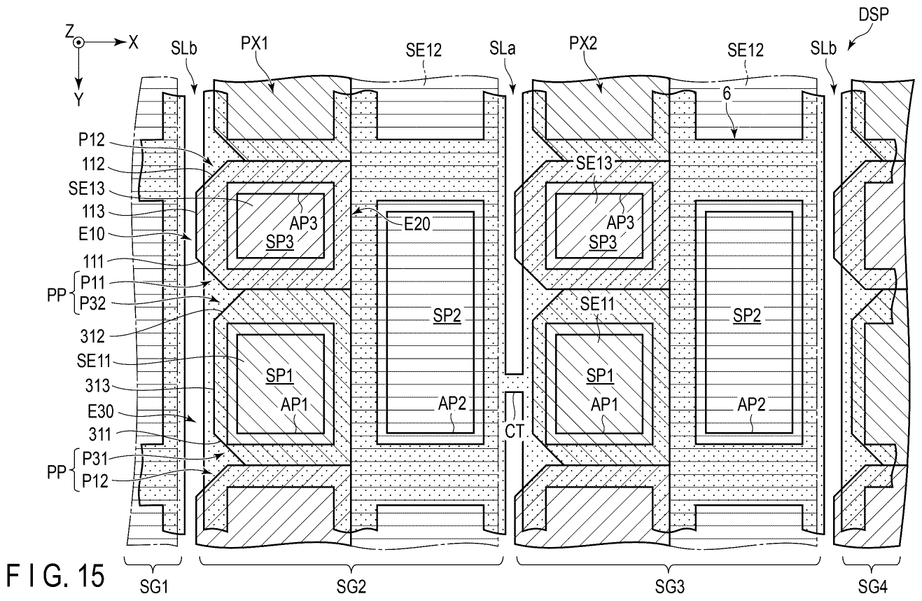

FIG. 15 is a schematic plan view showing configuration examples applicable to the partition 6 and the sealing layers SE11, SE12, and SE13 according to the present embodiment. The present embodiment differs from the first embodiment in that both of the sealing layers SE11 and SE13 include exposing portions. That is, the configuration of the present embodiment corresponds to the combination of the sealing layer SE13 in the first embodiment and the sealing layer SE11 in the second embodiment.

A greater exposing portion PP is formed by the exposing portions P11 and P32 between the end 111 of the sealing layer SE13 and the end 312 of the sealing layer SE11. Similarly, the greater exposing portion PP is formed by the exposing portions P12 and P31 between the end 112 of the sealing layer SE13 and the end 311 of the sealing layer SE11.

The formation of such exposing portions PP allows the etching solution to more readily intrude between the partition 6 and the sealing layer SE13. Thus, the stacked film FL3 hardly remains on the partition 6. Thus, differences in the degree of removal of the stacked film FL3 in the display area DA are minimized.

The present embodiment can achieve the same effects as those of the first embodiment.

The following will describe other configuration examples in the present embodiment.

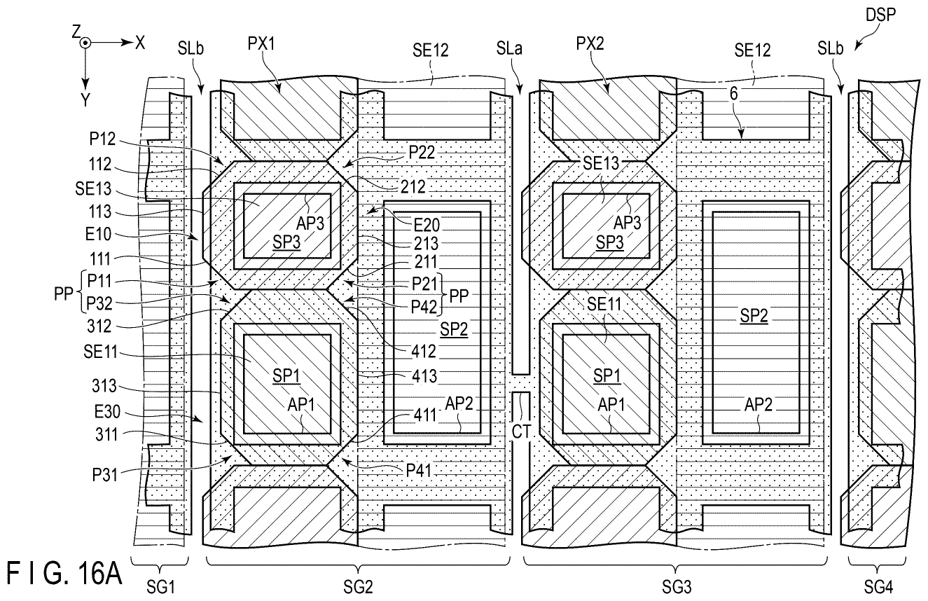

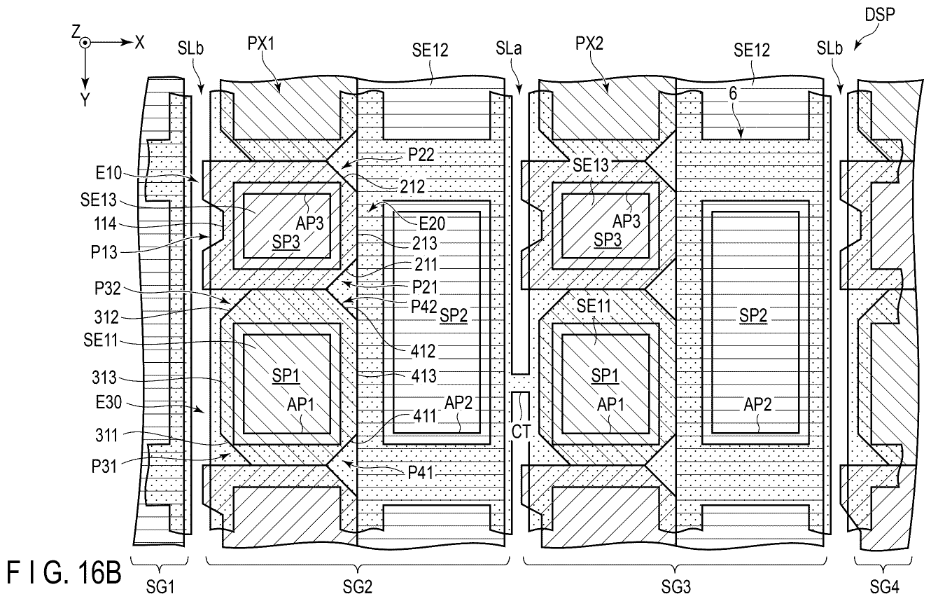

FIG. 16A and FIG. 16B are schematic plan views showing another configuration example applicable to the sealing layers SE11 and SE13 according to the present embodiment.

The configuration shown in FIG. 16A corresponds to a combination of the sealing layer SE13 shown in FIG. 11A and the sealing layer SE11 shown in FIG. 14. The exposing portion PP is formed in the example shown in FIG. 16A as well. Further, the configuration shown in FIG. 16B corresponds to a combination of the sealing layer SE13 shown in FIG. 11C and the sealing layer SE11 shown in FIG. 14. The combination of the sealing layers SE11 and SE13 is not limited to the above example.

In the present embodiment, the lower electrode LE3 corresponds to the first lower electrode, the lower electrode LE1 corresponds to the second lower electrode, the stacked film FL3 corresponds to the first stacked film, the stacked film FL1 corresponds to the second stacked film, the sealing layer SE13 corresponds to the first sealing layer, the sealing layer SE11 corresponds to the second sealing layer, the pixel PX1 corresponds to the first pixel, the pixel PX2 corresponds to the second pixel, the end portion E10 corresponds to the first end portion, the end portion E20 corresponds to the second end portion, the end portion E30 corresponds to the third end portion, and the end portion E40 corresponds to the fourth end portion.

### Fourth Embodiment

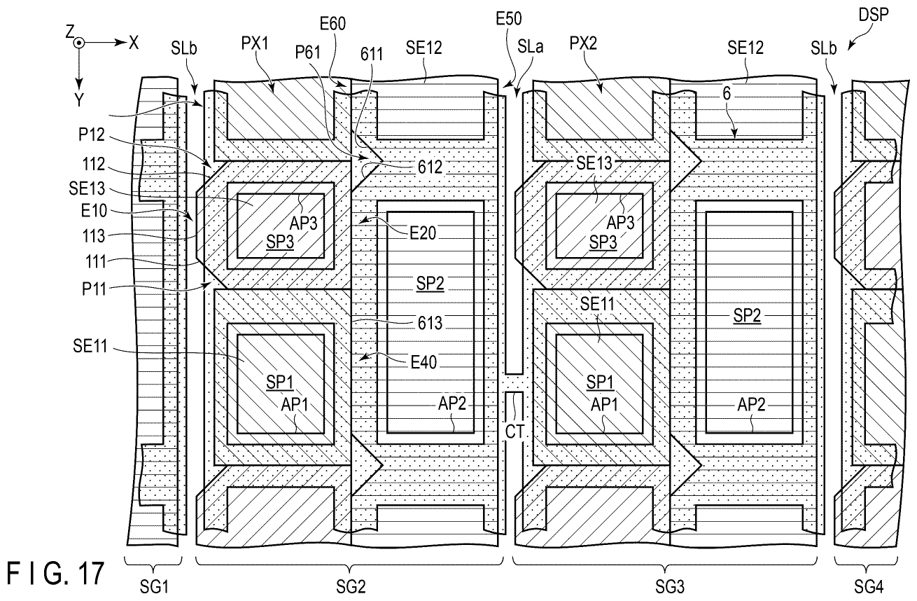

FIG. 17 is a schematic plan view showing configuration examples applicable to the partition 6 and the sealing layers SE11, SE12, and SE13 according to the present embodiment. The present embodiment differs from the first embodiment in that the sealing layer SE12 includes an exposing portion.

The sealing layer SE12 includes end portions E50 and E60. The end portion E50 is located on the slit SL side, and the end portion E60 is located on the side opposite to the end portion E50 in the first direction X. The end portion E60 contacts the sealing layers SE11 an SE13.

The end portion E60 includes a plurality of exposing portions P61. In the example shown in FIG. 17, the plurality of exposing portions P61 are arranged with intervals in the second direction Y. The exposing portion P61 is formed to be recessed toward the pixel aperture AP2.

For example, the exposing portion P61 corresponds to an area surrounded by the sealing layers SE11, SE12, and SE13. With respect to the partition 6, the exposing portion P61 exposes the upper portion 62 of the partition 6 in plan view (shown in FIG. 3 and FIG. 4).

The exposing portion P61 has a substantially triangular shape in plan view. The shape is not limited to this example. The end portion E60 includes ends 611 and 612 defining the exposing portion P61. In plan view, for example, the end 611 extends in a direction forming an acute angle clockwise with respect to the first direction X, and, for example, the end 612 extends in a direction forming an acute angle counterclockwise with respect to the first direction X. The inclination angles of the ends 611 and 612 can be modified as appropriate.

The ends 611 and 612 do not overlap the pixel aperture AP2. The end portion E60 further includes an end 613 connecting the ends 611 and 612 to each other. The end 613 extends in the second direction Y. The end 613 contacts the end portions E20 and E40 of the respective sealing layers SE11 and SE13.

The present embodiment can achieve the same effects as those of the first embodiment. In the present embodiment, the sealing layer SE12, which is formed second, has the exposing portion P61. In this case, at the end portions E20 and E40 of the respective sealing layers SE11 and SE13, respective parts facing the ends 611 and 612 and not contacting the sealing layer SE12 are formed. In the example shown in FIG. 14, the exposing portion P61 further may potentially be an intrusion path of etching liquid and the like that remove the stacked film FL3.

The gap GP between the partition 6 and the sealing layer SE13 is open toward the exposing portion P61. Thus, in the present embodiment as well, the etching liquid readily intrudes between the partition 6 and the sealing layer SE13 in the process PR8 shown in FIG. 9. Thus, the stacked film FL3 hardly remains on the partition 6. Thus, differences in the degree of removal of the stacked film FL3 in the display area DA are minimized.

In the example shown in FIG. 17, the sealing layer SE13 includes the exposing portions P11 and P12. The sealing layer SE13 may not include exposing portions. Further, the sealing layer SE11 does not include exposing portions in this example. The sealing layer SE11 may include exposing portions.

The exposing portion only needs to overlap the partition 6, and its planar shape is not limited to those described in the first to fourth embodiments. The planar shape of the exposing portion may be formed solely of curved parts, or both of straight-line parts and curved parts.

In the present embodiment, the lower electrode LE2 corresponds to the first lower electrode, the lower electrode LE1 corresponds to the second lower electrode, the stacked film FL2 corresponds to the first stacked film, the stacked film FL1 corresponds to the second stacked film, the organic layer OR2 corresponds to the first organic layer, the organic layer OR1 corresponds to the second organic layer, the sealing layer SE12 corresponds to the first sealing layer, and the sealing layer SE11 corresponds to the second sealing layer.

### Fifth Embodiment

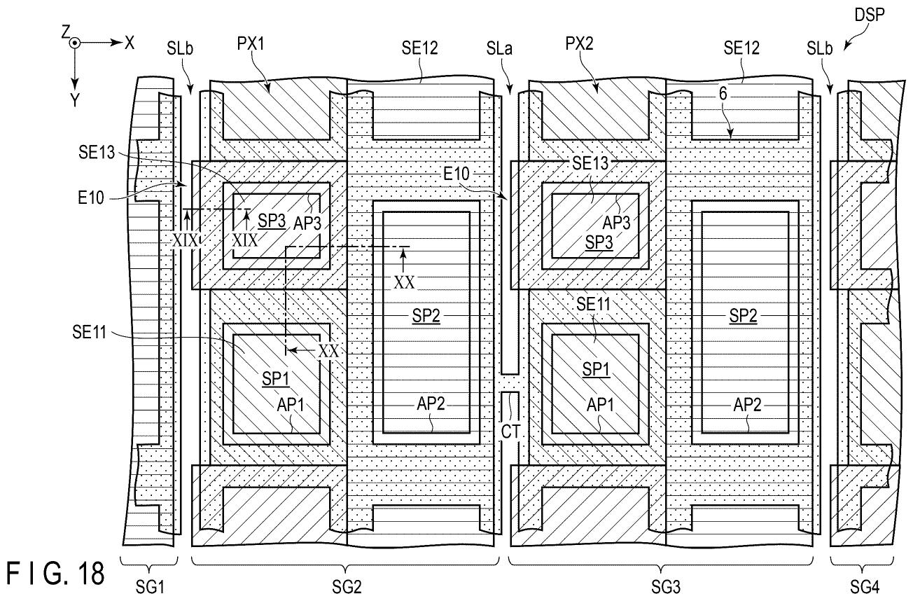

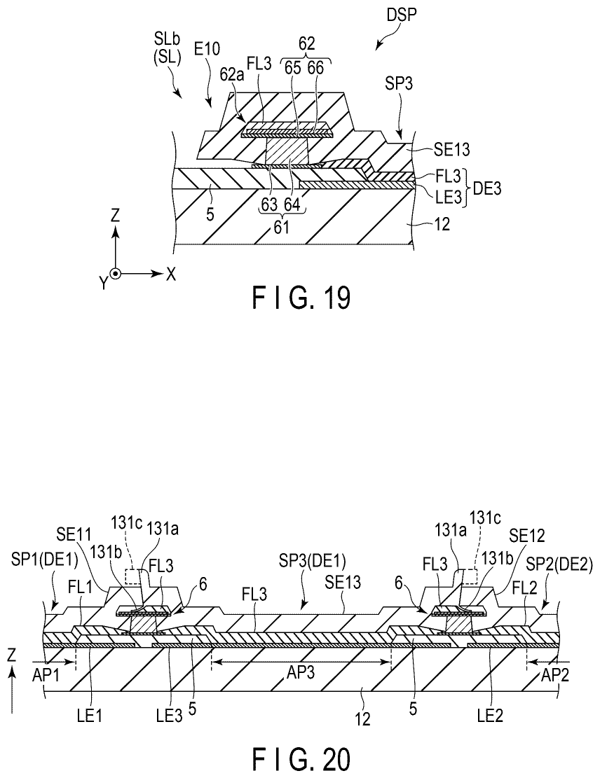

FIG. 18 is a schematic plan view showing configuration examples applicable to the partition 6 and the sealing layers SE11, SE12, and SE13 according to the present embodiment. FIG. 19 is a schematic cross-sectional view of the display device DSP along the XIX-XIX line of FIG. 18. The present embodiment differs from the above embodiments in that the sealing layer does not include exposing portions.

As shown in FIG. 18, the connecting portion CT connects the segments SG2 and SG3 to each other. More specifically, the connecting portion CT is located between the sealing layer SE12 of the pixel PX1 and the sealing layer SE11 of the pixel PX2 of the segment SG2. That is, the connecting portion CT is not located between the subpixels SP3 of the segments SG2 and SG3.

Part of the sealing layer SE13 overlaps the slit SL. As shown in FIG. 19, the end portion E10 of the sealing layer SE13 is provided to drop in the slit SL. In this case, the end portion E10 covers an end portion 62a of the upper portion 62 located on the slit SL side. FIG. 19 shows the example in which the sealing SE13 drops in the slit SLb. Similarly, the sealing layer SE13 of the pixel PX2 is provided to drop in the slit SLa.

The stacked film FL3 is located between the partition 6 and the sealing layer SE13. That is, the sealing layer SE13 covers the upper portion 62 of the partition 6 and the stacked film FL3 provided on the upper portion 62. As shown in FIG. 8, the gaps GP are formed between the partition 6 and the sealing layer SE11 and between the partition 6 and the sealing layer SE12.

FIG. 20 is a schematic cross-sectional view of the display device DSP along the XX-XX line of FIG. 18. The end portion of the sealing layer SE13 includes the protrusion portion 131a protruding upward above the partition 6. The end portion of the sealing layer SE13 further includes the extending portion 131b extending toward the gaps formed between the respective sealing layers SE11 and SE12 and the upper portion 62 of the partition 6. These gaps are formed by removing the stacked films FL1 and FL2 during the manufacturing process.

The stacked film FL3 is located between the partition 6 and the sealing layer SE13. The stacked film FL3 is surrounded by the partition 6 and the sealing layer SE13 including the extending portion 131b. That is, the gap GP between the partition 6 and the sealing layer SE13 is not open.

Thus, in the process PR8 shown in FIG. 9, the etching liquid does not readily intrude between the partition 6 and the end portion E10 of the sealing layer SE13. That is, the stacked film FL3 tends to remain on the partition 6. Thus, differences in the degree of removal of the stacked film FL3 in the display region DA are minimized.

Further, the stacked film FL3 is surrounded by the partition 6 and the sealing layer SE13 including the extending portion 131b. Thus, infiltration of the etching solution from above toward the gap is further suppressed, and the stacked film FL3 tends to remain on the partition 6.

Consequently, non-uniform reflection caused by differences in the degree of removal of the stacked film FL3 above the partition 6 is suppressed. Thus, the display quality of the display device DSP is improved.

Further, in the present embodiment, the connecting portion CT is provided on the side of the subpixel SP1. That is, the connecting portion CT is not provided on the side of the subpixel SP3. Thus, as shown in FIG. 19, the end portion E10 of the sealing layer SE13 can cover the end portion 62a of the upper portion 62 of the partition 6.

That is, the gap between the partition 6 and the sealing layer SE13 is not open. Thus, infiltration of the etching solution and the like toward the gap is further suppressed, and the stacked film FL3 tends to remain on the partition 6. Consequently, non-uniform reflection caused by differences in the degree of removal of the stacked film FL3 above the partition 6 is further suppressed.

Further, in the process PR8 in FIG. 9, when a resist is applied for processing the stacked film FL3 and the sealing layer SE13, bubbles may occur at positions overlapping the slit SL. If the process for forming the display element DE3 is performed while bubbles remain at such positions, the bubbles may burst during the vacuum drying of the resist for patterning the stacked film FL3 and the sealing layer SE13, causing an area that should be covered with the resist to be exposed.

As in the present embodiment, the end E10 of the sealing layer SE13 dropping into the position overlapping the slit SL can reduce the step height at the slit SL. This configuration can suppress the generation of bubbles during the resist application. The present embodiment can improve the yield of the display device DSP.

In the present embodiment, as indicated by the broken line in FIG. 20, the end portion of the sealing layer SE13 may further include the part 131c overlapping the other sealing layers SE11 and SE12. Further, the end portion of the sealing layer SE12 may include a protrusion portion 121a protruding upward (shown in FIG. 3 or FIG. 4). Further, the protrusion portion 121a is located higher than the sealing layer SE11 above the partition 6 between the subpixels SP1 and SP2. The protrusion portion 121a may further include the part 121c overlapping the sealing layer SE11 (shown in FIG. 3 or FIG. 4).

In the present embodiment, the lower electrode LE3 corresponds to the first lower electrode, the lower electrode LE1 corresponds to the second lower electrode, the lower electrode LE2 corresponds to the third lower electrode, the stacked film FL3 corresponds to the first stacked film, the stacked film FL1 corresponds to the second stacked film, the stacked film FL2 corresponds to the third stacked film, the organic layer OR3 corresponds to the first organic layer, the organic layer OR2 corresponds to the second organic layer, the organic layer OR1 corresponds to the third organic layer, the sealing layer SE13 corresponds to the first sealing layer, the sealing layer SE11 corresponds to the second sealing layer, the sealing layer SE12 corresponds to the third sealing layer, the pixel PX1 corresponds to the first pixel, the pixel PX2 corresponds to the second pixel, the slit SLa corresponds to the first slit, the slit SLb corresponds to the second slit, the segment SG2 corresponds to the first segment, the segment SG3 corresponds to the second segment, the protrusion portion 131a corresponds to the first protrusion portion, the extending portion 131b corresponds to the first extending portion, and the portion 131c corresponds to the part overlapping the second sealing layer.

The display device DSP configured in this manner can improve display quality. The above embodiments can achieve various suitable effects in addition to the above effects.

All of the display devices that can be implemented by a person of ordinary skill in the art through arbitrary design changes to the display device described above as the embodiment of the present invention come within the scope of the present invention as long as they are in keeping with the spirit of the present invention. Various types of the modified examples are easily conceivable within the category of the ideas of the present invention by a person of ordinary skill in the art and the modified examples are also considered to fall within the scope of the present invention. For example, even if a person of ordinary skill in the art arbitrarily modifies each of the embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from each of the embodiments and are self-explanatory from the descriptions of the specification or can be arbitrarily conceived by a person of ordinary skill in the art are considered as the effects of the present invention as a matter of course.

What is claimed is

1. A display device, comprising:
a display area in which a plurality of pixels each including a first lower electrode and a second lower electrode are provided;
a rib layer including a plurality of pixel apertures respectively located in the first lower electrode and the second lower electrode;
a partition surrounding each of the plurality of pixel apertures and including a conductive lower portion provided above the rib layer and an upper portion having an end portion protruding relative to a side surface of the lower portion;
a first stacked film provided above the first lower electrode and including a first organic layer;
a second stacked film provided above the second lower electrode and including a second organic layer different from the first organic layer;
a first sealing layer formed of an inorganic insulating material, covering the first stacked film, and provided above the partition; and
a second sealing layer formed of an inorganic insulating material, covering the second stacked film, and provided above the partition, wherein
the first sealing layer and the second sealing layer contact each other above the partition, and
the first sealing layer includes at least one exposing portion recessed toward the pixel aperture and exposing the partition in plan view.

2. The display device of claim 1, wherein
the plurality of pixels include a first pixel and a second pixel arranged in a first direction,
the first sealing layer and the second sealing layer are arranged in a second direction orthogonal to the first direction,
the partition includes a slit extending in the second direction between the first pixel and the second pixel,
the first sealing layer provided in the first pixel includes:
a first end portion located on a side of the slit; and
a second end portion located on a side opposite to the first end portion in the first direction, and
at least one of the first end portion and the second end portion includes the at least one exposing portion.

3. The display device of claim 2, wherein
at least one of the first end portion and the second end portion includes the plurality of exposing portions.

4. The display device of claim 2, wherein
the first end portion includes the at least one exposing portion.

5. The display device of claim 4, wherein
the first end portion includes two exposing portions respectively located on both sides of the first end portion in the second direction.

6. The display device of claim 4, wherein
the first end portion includes the exposing portion located at a center of the first end portion in the second direction.

7. The display device of claim 2, wherein
each of the first end portion and the second end portion includes the at least one exposing portion.

8. The display device of claim 7, wherein
the at least one exposing portion of the first end portion includes the exposing portion located at the center of the first end portion in the second direction, and
the at least one exposing portion of the second end portion includes two exposing portions respectively located on both sides of the second end portion in the second direction.

9. The display device of claim 2, wherein
the second sealing layer includes:
a third end portion located on a side of the slit; and
a fourth end portion located on a side opposite to the third end portion in the first direction, and
at least one of the third end portion and the fourth end portion includes the at least one exposing portion.

10. The display device of claim 9, wherein
the third end portion includes the at least one exposing portion.

11. The display device of claim 9, wherein
each of the third end portion and the fourth end portion includes the at least one exposing portion.

12. The display device of claim 2, wherein
the first sealing layer includes a first protrusion portion located higher than the second sealing layer above the partition.

13. The display device of claim 12, wherein
the first protrusion portion includes a part overlapping the second sealing layer.

14. The display device of claim 12, wherein
the first sealing layer further includes a first extending portion extending toward a gap formed between the second sealing layer and the partition.

15. A display device, comprising:
a display area in which a plurality of pixels each including a first lower electrode, a second lower electrode, and a third lower electrode are provided;
a rib layer including a plurality of pixel apertures respectively located in the first lower electrode, the second lower electrode, and the third lower electrode;
a partition surrounding each of the plurality of pixel apertures and including a conductive lower portion provided above the rib layer and an upper portion having an end portion protruding relative to a side surface of the lower portion;
a first stacked film provided above the first lower electrode and including a first organic layer;
a second stacked film provided above the second lower electrode and including a second organic layer different from the first organic layer;
a third stacked film provided above the third lower electrode and including a third organic layer different from the first organic layer and the second organic layer;
a first sealing layer formed of an inorganic insulating material, covering the first stacked film, and provided above the partition;
a second sealing layer formed of an inorganic insulating material, covering the second stacked film, and provided above the partition; and
a third sealing layer formed of an inorganic insulating material, covering the third stacked film, and provided above the partition, wherein
the plurality of pixels include a first pixel and a second pixel arranged in a first direction,
the first sealing layer and the second sealing layer are arranged with the third sealing layer in the first direction,
the first sealing layer and the second sealing layer are arranged in a second direction orthogonal to the first direction,
the partition includes a first slit extending in the second direction between the first pixel and the second pixel,
the first sealing layer, the second sealing layer, and the third sealing layer contact each other above the partition,
the first sealing layer includes a first protrusion portion located higher than the second sealing layer and the third sealing layer above the partition,
the first sealing layer covers an end portion of the upper portion located on a side of the first slit, and
the first stacked film is located between the partition and the first sealing layer.

16. The display device of claim 15, wherein
a gap is formed between the partition and the second sealing layer and the third sealing layer.

17. The display device of claim 16, wherein
the partition includes:
a first segment and a second segment separated by the first slit; and
a connecting portion crossing the first slit to connect the first segment and the second segment to each other, wherein
the first segment includes the first pixel,
the second segment includes the second pixel, and
the connecting portion is located between the third sealing layer of the first pixel and the second sealing layer of the second pixel.

18. The display device of claim 17, wherein
the partition further includes a second slit in which the connecting portion is not provided.

19. The display device of claim 15, wherein
the first protrusion portion includes a part overlapping the second sealing layer.

20. The display device of claim 15, wherein
the first sealing layer further includes a first extending portion extending toward a gap formed between the second sealing layer and the partition.
